(19) United States
(12) Patent Application Publication
(10) Pub. No.: US 2026/0215063 A1
(43) Pub. Date: Jul. 23, 2026

(54) DISPLAY DEVICE AND ELECTRONIC DEVICE

(71) Applicant: Samsung Display Co., Ltd., Yongin-si (KR)

(72) Inventors: Ji Sun KIM, Yongin-si (KR); Sun Hwa LEE, Yongin-si (KR); Kwi Hyun KIM, Yongin-si (KR); Se Hyun LEE, Yongin-si (KR); Kyung Hoon CHUNG, Yongin-si (KR)

(21) Appl. No.: 19/381,843

(22) Filed: Nov. 6, 2025

(30) Foreign Application Priority Data
Jan. 22, 2025 (KR) 10-2025-0009341

(51) Int. Cl. H10H 29/856; H10H 20/831; H10H 29/49

(52) U.S. Cl. CPC H10H 29/856; H10H 20/831; H10H 29/49

(57) ABSTRACT

A display device according to one or more embodiments includes a pixel electrode and a common electrode spaced apart above a substrate, a first reflective layer and a second reflective layer separated from each other and respectively above the pixel electrode and the common electrode, and a light-emitting element above the first reflective layer and the second reflective layer and electrically connected between the pixel electrode and the common electrode.

### CROSS-REFERENCE TO RELATED APPLICATION

The present application claims priority to, and the benefit of, Korean Patent Application No. 10-2025-0009341, filed on January 22, 2025, in the Korean Intellectual Property Office, the entire disclosure of which is incorporated herein by reference.

### BACKGROUND

### Field

Embodiments of the present disclosure relate to a display device and an electronic device capable of displaying an image.

### Description of the Related Art

With the advance of information-oriented society, more and more demands are placed on display devices and electronic devices capable of displaying images in various ways. Accordingly, various types of display devices and electronic devices including pixels for displaying images are being developed. A display device may be provided alone, or may be included in an electronic device and used as a display screen of the electronic device.

### SUMMARY

Aspects of the present disclosure provide a display device and an electronic device capable of improving light efficiency.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a pixel electrode and a common electrode spaced apart above a substrate, a first reflective layer and a second reflective layer separated from each other and respectively above the pixel electrode and the common electrode, and a light-emitting element above the first reflective layer and the second reflective layer and electrically connected between the pixel electrode and the common electrode.

The first reflective layer may be above an end portion of the pixel electrode overlapping the light-emitting element, and exposes another portion of the pixel electrode.

The second reflective layer may be above an end portion of the common electrode overlapping the light-emitting element and adjacent to the pixel electrode, and may expose another portion of the common electrode.

The first reflective layer may cover a side surface of the end portion of the pixel electrode, wherein the second reflective layer covers a side surface of the end portion of the common electrode.

The first reflective layer may have a length that is less than a length of the pixel electrode in an extension direction of the pixel electrode, may have a width that is greater than a width of the pixel electrode in a second direction crossing the extension direction, may cover the end portion of the pixel electrode, and may expose another end portion of the pixel electrode.

The first reflective layer and the second reflective layer may be symmetrical with respect to the light-emitting element.

The first reflective layer may cover a side surface of an end portion of the pixel electrode, wherein the second reflective layer covers a side surface of an end portion of the common electrode.

The first reflective layer may entirely cover the pixel electrode, wherein the second reflective layer entirely covers the common electrode.

The first reflective layer may expose a portion of a top surface of the pixel electrode not overlapping the light-emitting element, wherein the second reflective layer exposes a portion of a top surface of the common electrode not overlapping the light-emitting element.

The display device may further include an adhesive layer covering a portion of the first reflective layer and a portion of the second reflective layer below and overlapping the light-emitting element, a first connection electrode above the adhesive layer and connecting the pixel electrode or the first reflective layer and the light-emitting element, and a second connection electrode above the adhesive layer and connecting the common electrode or the second reflective layer and the light-emitting element.

The first connection electrode may contact the light-emitting element above the portion of the first reflective layer, and may contact the first reflective layer above another portion of the first reflective layer, wherein the second connection electrode contacts the light-emitting element above the portion of the second reflective layer, and contacts the second reflective layer above another portion of the second reflective layer.

The first reflective layer and the second reflective layer may respectively expose a top surface of the pixel electrode contacting the first connection electrode, and a top surface of the common electrode contacting the second connection electrode.

The light-emitting element may include a semiconductor stack above the adhesive layer, a first contact electrode on at least one side surface of the semiconductor stack and contacting the first connection electrode above the first reflective layer, and a second contact electrode on at least one side surface of the semiconductor stack and contacting the second connection electrode above the second reflective layer.

The display device may further include a power bus line electrically connected to the common electrode and including a wiring layer extended from the common electrode.

The second reflective layer may extend to and may cover the wiring layer.

According to an aspect of the present disclosure, there is provided an electronic device including a display module including a display panel, a memory for storing an image data signal or an input control signal, and a processor for transmitting the image data signal or the input control signal to the display module, wherein the display panel includes a pixel electrode and a common electrode spaced apart from each other above a substrate, a first reflective layer and a second reflective layer separated from each other and respectively above the pixel electrode and the common electrode, and a light-emitting element above the first reflective layer and the second reflective layer and electrically connected between the pixel electrode and the common electrode.

The first reflective layer may be above an end portion of the pixel electrode overlapping the light-emitting element, and may expose another portion of the pixel electrode, wherein the second reflective layer is above an end portion of the common electrode overlapping the light-emitting element and adjacent to the pixel electrode, and exposes another portion of the common electrode.

The first reflective layer may cover a side surface of an end portion of the pixel electrode, wherein the second reflective layer covers a side surface of an end portion of the common electrode.

The first reflective layer may entirely cover the pixel electrode, wherein the second reflective layer entirely covers the common electrode.

The first reflective layer may expose a portion of a top surface of the pixel electrode not overlapping the light-emitting element, wherein the second reflective layer exposes a portion of a top surface of the common electrode not overlapping the light-emitting element.

The display device and the electronic device according to some embodiments may include a light-emitting element and a reflective layer located beneath the light-emitting element. Accordingly, the light efficiency of the display device and the electronic device may be improved.

In some embodiments, the reflective layer may cover an end portion of a pixel electrode layer to protect the pixel electrode layer. Accordingly, the reliability of the display device and the electronic device may be secured.

However, aspects according to the embodiments of the present disclosure are not limited to those described above and various other aspects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating a display device according to one or more embodiments;

FIG. 2 is a plan view illustrating a display panel according to one or more embodiments;

FIG. 3 is a block diagram illustrating a display device according to one or more embodiments;

FIG. 4 is an equivalent circuit diagram illustrating a sub-pixel according to one or more embodiments;

FIG. 5 is a waveform diagram showing driving signals of a sub-pixel according to one or more embodiments;

FIG. 6 is a plan view illustrating a display panel according to one or more embodiments;

FIG. 7 is a plan view illustrating a display panel according to one or more embodiments;

FIG. 8 is a plan view illustrating a display panel according to one or more embodiments;

FIG. 9 is a cross-sectional view illustrating a display panel according to one or more embodiments;

FIG. 10 is a cross-sectional view showing area A1 of FIG. 9 in detail;

FIG. 11 is a plan view illustrating a display panel according to one or more embodiments;

FIG. 12 is a cross-sectional view illustrating a display panel according to one or more embodiments;

FIG. 13 is a plan view illustrating a display panel according to one or more embodiments;

FIG. 14 is a cross-sectional view illustrating a display panel according to one or more embodiments;

FIG. 15 is a cross-sectional view illustrating a power bus line according to one or more embodiments;

FIG. 16 is a cross-sectional view illustrating a power bus line according to one or more embodiments;

FIG. 17 is a block diagram of an electronic device according to one or more embodiments; and

FIG. 18 is schematic views of electronic devices according to various embodiments

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

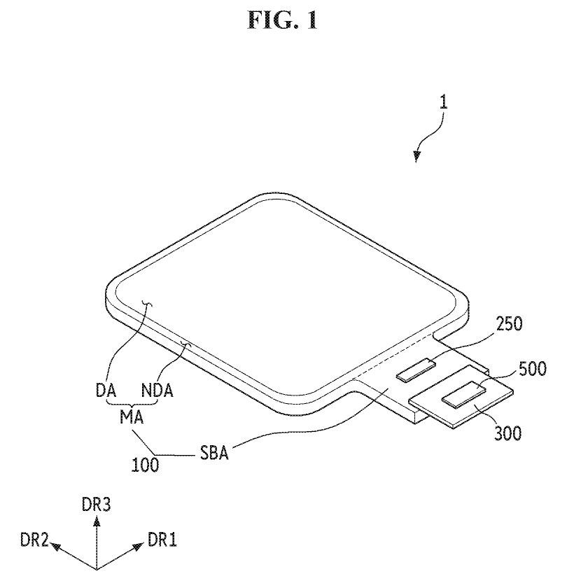

FIG. 1 is a perspective view illustrating a display device according to one or more embodiments.

Referring to FIG. 1, a display device 1 may be a device capable of providing an image, such as a moving image or a still image. For example, the display device 1 may be a device that includes a display module including a display panel 100, and thus may display an image. As an example, the display device 1 may refer to all electronic devices that provide a display screen on which an image may be displayed or include a display module for displaying an image. The display device 1 may be included in an electronic device that provides a display screen and may form the display screen of the electronic device.

For example, the display device 1 may be included in various electronic devices, such as televisions, laptop computers, monitors, billboards and the Internet of Things (IOT), as well as portable electronic devices, such as mobile phones, smart phones, tablet personal computers (tablet PCs), smart watches, watch phones, mobile communication terminals, electronic notebooks, electronic books, portable multimedia players (PMPs), navigation systems and ultra mobile PCs (UMPCs), and may be used as a display screen. In addition, the display device 1 may be included in other electronic devices, such as a virtual reality (VR) device, an augmented reality (AR) device, or the like and used to display an image in the electronic device.

In FIG. 1, a display module, which is a main component of the display device 1, is illustrated. In one or more embodiments, the display device 1 (or an electronic device including a display module) may further include an additional component. For example, the display device 1 may further include a housing or a casing that accommodates the display module of FIG. 1.

In one or more embodiments, the display device 1 may be a light-emitting display device, such as an organic light-emitting display using an organic light-emitting diode, a quantum dot light-emitting display including a quantum dot light-emitting layer, an inorganic light-emitting display including an inorganic semiconductor, and a micro or nano light-emitting display using a micro or nano light-emitting diode (LED). Hereinafter, as an example of the display device 1 to which embodiments may be applied, a micro or nano light-emitting display including a micro or nano light-emitting diode will be disclosed. However, the embodiments are not limited thereto. For example, the type of light-emitting element included in the display device 1 is not limited to a micro or nano light-emitting diode, and the display device 1 may include a light-emitting element of another type and/or shape. Further, the display device 1 according to embodiments is not limited to a light-emitting display device, and the type and/or shape of the display device 1 may vary depending on embodiments.

The display device 1 may include a display panel 100, a display driving circuit 250, a circuit board 300, and a power supply unit 500. The display panel 100, the display driving circuit 250, the circuit board 300, and the power supply unit 500 may be included in the display module of the display device 1.

In one or more embodiments, the display panel 100 may have a substantially quadrilateral planar shape. For example, the display panel 100 may have a substantially quadrilateral shape on the plane defined by a first direction DR1 and a second direction DR2 crossing each other. The corners of the display panel 100 may be rounded or may be right-angled. The planar shape of the display panel 100 is not limited to the rectangular shape, and may be formed in another polygonal shape, a circular shape or an elliptical shape. The display panel 100 may be substantially flat, but is not limited thereto. For example, the display panel 100 may include a curved portion in at least a part (e.g., left and right ends). In one or more embodiments, the display panel 100 may be formed to be flexible so that it can be curved, bent, folded, or rolled.

The display panel 100 may include a main region MA where an image is displayed. In one or more embodiments, the display panel 100 may further include a sub-region SBA.

The main region MA may include a display area DA displaying an image and a non-display area NDA that is a peripheral area of the display area DA. The display area DA may include pixels to display an image. Each of the pixels may include a plurality of sub-pixels. For example, each of the pixels may include a first sub-pixel that emits light of a first color, a second sub-pixel that emits light of a second color, and a third sub-pixel that emits light of a third color, but the embodiments are not limited thereto.

The sub-region SBA may protrude from one side of the main region MA in the second direction DR2 (e.g., the longitudinal direction). Although FIG. 1 shows a state in which the sub-region SBA is unfolded, the sub-region SBA may be bent. When the sub-region SBA is bent, the sub-region SBA may overlap the main region MA in a third direction DR3, which is the thickness direction of the display panel 100, and may be located on the bottom surface of the display panel 100. The display driving circuit 250 may be arranged in the sub-region SBA.

The display driving circuit 250 may generate signals and voltages (for example, driving signals and driving voltages of the display panel 100) for driving the display panel 100. The display driving circuit 250 may be formed as an integrated circuit (IC) and attached onto the display panel 100 by a chip-on-glass (COG) method, a chip-on-plastic (COP) method, or an ultrasonic bonding method, but the present disclosure is not limited thereto. For example, the display driving circuit 250 may be attached onto the circuit board 300 by a chip-on-film (COF) method.

The circuit board 300 may be attached to one end of the sub-region SBA of the display panel 100, and may be electrically connected to the display panel 100 and the display driving circuit 250. The display panel 100 and the display driving circuit 250 may receive digital video data, timing signals, and driving voltages through the circuit board 300. The circuit board 300 may be a flexible printed circuit board, a printed circuit board, or a flexible film, such as a chip on film.

The power supply unit 500 may generate panel driving voltages according to a power voltage supplied from the outside. The power supply unit 500 may be formed as an integrated circuit (IC) and attached to the circuit board 300 by a COF method.

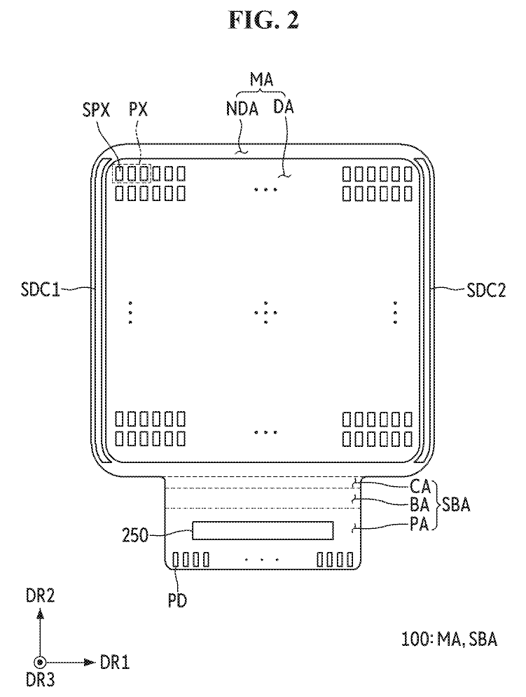

FIG. 2 is a plan view illustrating a display panel according to one or more embodiments. In FIG. 2, the sub-region SBA is illustrated in an unfolded state.

Referring to FIGS. 1 and 2, the display panel 100 may include the main region MA and the sub-region SBA.

The main region MA may include the display area DA and the non-display area NDA. The display area DA may occupy most of the main region MA.

The display area DA may include pixels PX for displaying an image. Each of the pixels PX may include a plurality of sub-pixels SPX. The pixel PX may be defined as a minimum unit sub-pixel group capable of expressing a white grayscale. For example, the pixel PX may include three sub-pixels SPX that emit light of different colors. However, the number, type, and/or ratio of the sub-pixels SPX included in each pixel PX may vary depending on embodiments.

The non-display area NDA may be located adjacent to the display area DA. For example, the non-display area NDA may surround the display area DA. The non-display area NDA may be an edge area of the display panel 100.

In one or more embodiments, a first scan driver SDC1 and a second scan driver SDC2 may be located in the non-display area NDA. The first scan driver SDC1 and the second scan driver SDC2 may be located on different respective sides of the display area DA. Each of the first scan driver SDC1 and the second scan driver SDC2 may be electrically connected to the display driving circuit 250 through a plurality of wires. Each of the first scan driver SDC1 and the second scan driver SDC2 may receive scan control signals inputted from the display driving circuit 250, may generate scan signals in response to the scan control signals, and may output the generated scan signals to scan lines.

Although FIG. 2 shows one or more embodiments in which the display device 1 (for example, the display panel 100) includes the first scan driver SDC1 and the second scan driver SDC2, the embodiments are not limited thereto. For example, the number or location of the scan driver included in the display device 1 may vary depending on embodiments.

The sub-region SBA may protrude from one side of the main region MA in the second direction DR2 (e.g., the longitudinal direction). The length of the sub-region SBA in the second direction DR2 may be less than the length of the main region MA in the second direction DR2. The length of the sub-region SBA in the first direction DR1 may be less than or equal to the length of the main region MA in the first direction DR1. The sub-region SBA may be bent, so that at least a part of the sub-region SBA may overlap the main region MA in the third direction DR3. For example, a part of the sub-region SBA may be located under the main region MA.

The sub-region SBA may include a connection area CA, a pad area PA, and a bending area BA.

The connection area CA may be an area protruding from one side of the main region MA in the second direction DR2. One side of the connection area CA may be in contact with the non-display area NDA of the main region MA, and the other side of the connection area CA may be in contact with the bending area BA.

The pad area PA may be an area on which pads PD and the display driving circuit 250 are arranged. The display driving circuit 250 may be attached to driving pads of the pad area PA using a conductive adhesive member, such as an anisotropic conductive film. The circuit board 300 may be attached to the pads PD of the pad area PA using a conductive adhesive member, such as an anisotropic conductive film. One side of the pad area PA may be in contact with the bending area BA.

The bending area BA may be an area being bent. When the display panel 100 is bent in the bending area BA, the pad area PA may be located under the connection area CA and the main region MA. The bending area BA may be located between the connection area CA and the pad area PA. One side of the bending area BA may be in contact with the connection area CA, and the other side of the bending area BA may be in contact with the pad area PA.

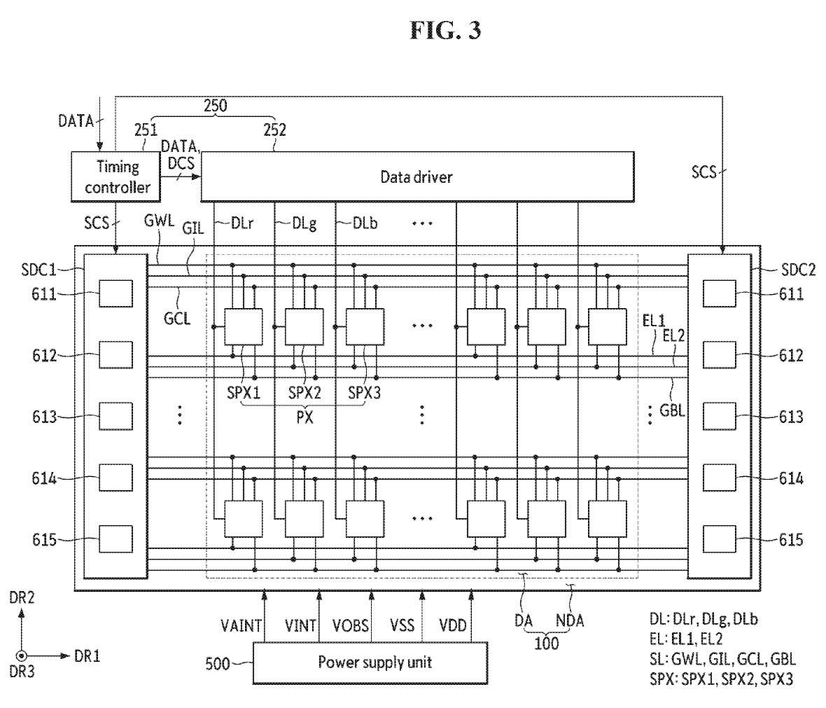

FIG. 3 is a block diagram illustrating a display device according to one or more embodiments.

Referring to FIG. 3, the display area DA may include pixels PX, scan lines SL, emission control lines EL, and data lines DL.

The pixels PX may be arranged in the first direction DR1 and the second direction DR2. For example, the pixels PX may be arranged in a matrix form in the first direction DR1 and the second direction DR2. The scan lines SL and the emission control lines EL may extend in the first direction DR1 and may be arranged in the second direction DR2. The data lines DL may extend in the second direction DR2 and may be arranged along the first direction DR1. The scan lines SL may include write scan lines GWL, initialization scan lines GIL, control scan lines GCL, and bias scan lines GBL. The configuration of the scan lines SL may be different according to the structure or driving method of the pixels PX.

Each of the pixels PX may include a plurality of sub-pixels SPX. For example, each of the pixels PX may include a first sub-pixel SPX1, a second sub-pixel SPX2, and a third sub-pixel SPX3. The first sub-pixel SPX1, the second sub-pixel SPX2, and the third sub-pixel SPX3 may emit light of a first color, light of a second color, and light of a third color, respectively. The light of the first color, the light of the second color, and the light of the third color may be red light (for example, light in a red wavelength band having a main peak wavelength of about 600 nm to about 750 nm), green light (for example, light in a green wavelength band having a main peak wavelength of about 480 nm to about 560 nm), and blue light (for example, light in a blue wavelength band having a main peak wavelength of about 370 nm to about 460 nm), respectively, but the present disclosure is not limited thereto. In one or more embodiments, the first sub-pixel SPX1, the second sub-pixel SPX2, and the third sub-pixel SPX3 of each of the pixels PX may be arranged in the first direction DR1. The number, type, arrangement structure, and/or emission wavelength of the sub-pixels SPX included in each of the pixels PX may vary depending on the embodiments.

Each of the sub-pixels SPX may be connected to any one of the write scan lines GWL, any one of the initialization scan lines GIL, any one of the control scan lines GCL, any one of the bias scan lines GBL, any one of the emission control lines EL, and any one of the data lines DL. In describing embodiments, “connection” may include “physical connection” and/or “electrical connection.”

Each of the plurality of sub-pixels SPX may receive the data voltage of the data line DL according to the write scan signal of the write scan line GWL. Each of the plurality of sub-pixels SPX may include a light-emitting element that emits light with a luminance corresponding to the data voltage. The plurality of sub-pixels SPX included in each pixel PX may be connected to the different data lines DL. For example, the first sub-pixel SPX1, the second sub-pixel SPX2, and the third sub-pixel SPX3 may be respectively connected to a first data line DLr, a second data line DLg, and a third data line DLb. Accordingly, the luminance of each of the first sub-pixel SPX1, the second sub-pixel SPX2, and the third sub-pixel SPX3 may be controlled individually.

In one or more embodiments, each of the pixels PX may be connected to two or more emission control lines EL, and an emission period (or on-duty ratio) of at least two of the sub-pixels SPX included in each pixel PX may be controlled independently and/or individually by different emission control signals supplied to the different emission control lines EL. For example, in each horizontal line (e.g., each pixel row) of the display area DA, a first emission control line EL1 and a second emission control line EL2, which are connected to different sub-pixels SPX among the sub-pixels SPX of the pixels PX arranged on the corresponding horizontal line, may be arranged. For example, the first emission control line EL1 may be connected to the first sub-pixels SPX1 of the pixels PX arranged on the corresponding horizontal line, and the second emission control line EL2 may be connected to the second sub-pixels SPX2 and the third sub-pixels SPX3 included in the pixels PX of the corresponding horizontal line.

The first sub-pixel SPX1 may emit light during a first emission period in response to a first emission control signal supplied through the first emission control line EL1. The first emission period may be a period during which a driving current may flow through the first sub-pixel SPX1 by the first emission control signal. The second sub-pixel SPX2 and the third sub-pixel SPX3 may emit light during a second emission period in response to a second emission control signal supplied through the second emission control line EL2. The second emission period may be a period during which a driving current may flow through the second sub-pixel SPX2 and the third sub-pixel SPX3 by the second emission control signal. The first emission period and the second emission period may be controlled independently or separately from each other.

In one or more embodiments, the duration of the first emission period may be different from the duration of the second emission period. For example, the duration of the first emission period may correspond to an on-duty ratio adjusted to allow the first sub-pixel SPX1 to emit light with a desired luminance according to a driving current improved or optimized according to the luminous efficiency of the first sub-pixel SPX1 (e.g., a driving current in a range in which the light-emitting element of the first sub-pixel SPX1 exhibits an improved or optimal consumption efficiency). The duration of the second emission period may correspond to an on-duty ratio adjusted to allow the second sub-pixel SPX2 and the third sub-pixel SPX3 to emit light with a desired luminance according to a driving current improved or optimized according to the luminous efficiency of the second sub-pixel SPX2 and the third sub-pixel SPX3 (e.g., a driving current in a range in which the light-emitting elements of the second sub-pixel SPX2 and the third sub-pixel SPX3 exhibit improved or optimal consumption efficiency). In this case, an emission control signal output unit 615 included in the first scan driver SDC1 and the second scan driver SDC2 may output emission control signals having different pulse widths to the first emission control line EL1 and the second emission control line EL2.

However, the embodiments are not limited thereto. For example, in one or more other embodiments, the first sub-pixel SPX1, the second sub-pixel SPX2, and the third sub-pixel SPX3 included in one pixel PX may be commonly connected to one emission control line EL. For example, one emission control line EL may be located in one horizontal line, and the sub-pixels SPX located in the one horizontal line may be commonly connected to the one emission control line EL. In this case, the emission periods of the first sub-pixel SPX1, the second sub-pixel SPX2, and the third sub-pixel SPX3 may be controlled by the emission control signal supplied to the one emission control line EL.

The first scan driver SDC1, the second scan driver SDC2, and the display driving circuit 250 may be located in the non-display area NDA.

Each of the first scan driver SDC1 and the second scan driver SDC2 may be electrically connected to the pixels PX through the scan lines SL and the emission control lines EL. For example, each of the first scan driver SDC1 and the second scan driver SDC2 may be electrically connected to the sub-pixels SPX of each pixel PX through the write scan lines GWL, the initialization scan lines GIL, the control scan lines GCL, the bias scan lines GBL, and the emission control lines EL.

Each of the first scan driver SDC1 and the second scan driver SDC2 may include a write scan signal output unit 611, an initialization scan signal output unit 612, a control scan signal output unit 613, a bias scan signal output unit 614, and the emission control signal output unit 615. Each of the write scan signal output unit 611, the initialization scan signal output unit 612, the control scan signal output unit 613, the bias scan signal output unit 614, and the emission control signal output unit 615 may receive a scan-timing control signal SCS from a timing controller 251.

The write scan signal output unit 611 may generate write scan signals in response to the scan-timing control signal SCS and may sequentially output them to the write scan lines GWL.

The initialization scan signal output unit 612 may generate initialization scan signals in response to the scan-timing control signal SCS and may sequentially output them to the initialization scan lines GIL.

The control scan signal output unit 613 may generate control scan signals in response to the scan-timing control signal SCS and may sequentially output them to the control scan lines GCL.

The bias scan signal output unit 614 may generate bias scan signals according to the scan-timing control signal SCS and output them sequentially to the bias scan lines GBL.

The emission control signal output unit 615 may generate emission control signals according to the scan-timing control signal SCS and may sequentially output them to the emission control lines EL. In one or more embodiments, when the sub-pixels SPX of each horizontal line are divided and connected to the plurality of emission control lines EL (e.g., the first emission control line EL1 and the second emission control line EL2 of each horizontal line), the emission control signal output unit 615 may output each emission control signal to the plurality of emission control lines EL for each horizontal period.

The display driving circuit 250 may include the timing controller 251 and a data driver 252.

The data driver 252 may be electrically connected to the pixels PX through the data lines DL. For example, the data driver 252 may be electrically connected to the sub-pixels SPX of each pixel PX through the first data line DLr, the second data line DLg, and the third data line DLb.

The data driver 252 may receive the digital video data DATA and the data-timing control signal DCS from the timing controller 251. The data driver 252 converts the digital video data DATA into analog data voltages in response to the data-timing control signal DCS, and outputs them to the data lines DL. The sub-pixels SPX may be selected by the write scan signal of the first scan driver SDC1 and the second scan driver SDC2, and data voltages may be supplied to the selected sub-pixels SPX.

The timing controller 251 may receive digital video data DATA and timing signals from the outside. The timing controller 251 may generate the scan-timing control signal SCS and the data-timing control signal DCS for controlling the display panel 100 in response to the timing signals. The timing controller 251 may output the scan-timing control signal SCS to the first scan driver SDC1 and the second scan driver SDC2. The timing controller 251 may output the digital video data DATA and the data-timing control signal DCS to the data driver 252.

The power supply unit 500 may generate panel driving voltages according to a power voltage supplied from the outside. For example, the power supply unit 500 may generate and supply a first driving voltage VDD, a second driving voltage VSS, a third driving voltage VINT, a fourth driving voltage VAINT, and a fifth driving voltage VOBS to the display panel 100. The first driving voltage VDD, the second driving voltage VSS, the third driving voltage VINT, the fourth driving voltage VAINT, and the fifth driving voltage VOBS may be supplied to the sub-pixels SPX through respective power lines connected between the power supply unit 500 and the sub-pixels SPX, and may be used to drive the sub-pixels SPX. According to the structure or operation method of the sub-pixels SPX, the number and/or type of panel driving voltages outputted from the power supply unit 500 may be changed.

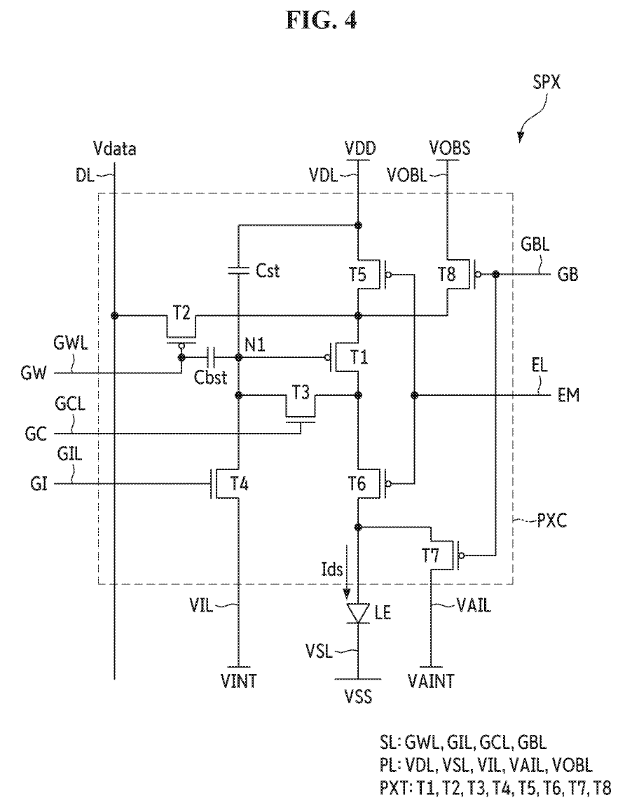

FIG. 4 is an equivalent circuit diagram illustrating a sub-pixel according to one or more embodiments. For example, FIG. 4 may be an equivalent circuit diagram showing one sub-pixel SPX among the sub-pixels SPX of FIGS. 2 and 3. For example, the sub-pixel SPX of FIG. 4 may be the first sub-pixel SPX1, the second sub-pixel SPX2, or the third sub-pixel SPX3 of FIG. 3. In one or more embodiments, the circuit configurations of the sub-pixels SPX constituting each pixel PX may be substantially the same.

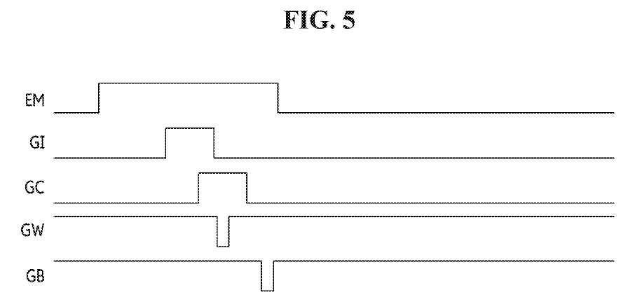

FIG. 5 is a waveform diagram showing driving signals of a sub-pixel according to one or more embodiments. For example, FIG. 5 shows a write scan signal GW, a control scan signal GC, an initialization scan signal GI, a bias scan signal GB and an emission control signal EM supplied to the scan lines SL and the emission control line EL of FIG. 4.

Referring to FIGS. 4 and 5 in addition to FIGS. 1 to 3, each of the sub-pixels SPX may include a pixel circuit PXC and a light-emitting element LE electrically connected to the pixel circuit PXC.

The sub-pixel SPX may be connected to at least one scan driver through the scan lines SL and the emission control line EL. For example, the sub-pixel SPX may be connected to the first scan driver SDC1 and the second scan driver SDC2 through the write scan line GWL, the initialization scan line GIL, the control scan line GCL, the bias scan line GBL, and the emission control line EL. The first scan driver SDC1 and the second scan driver SDC2 may output the write scan signal GW, the initialization scan signal GI, the control scan signal GC, the bias scan signal GB, and the emission control signal EM to the write scan line GWL, the initialization scan line GIL, the control scan line GCL, the bias scan line GBL, and the emission control line EL, respectively.

When the sub-pixel SPX is the first sub-pixel SPX1, the sub-pixel SPX may be connected to the first emission control line EL1 located on the corresponding horizontal line, and may receive the emission control signal EM (also referred to as “first emission control signal”) from the first emission control line EL1. When the sub-pixel SPX is the second sub-pixel SPX2 or the third sub-pixel SPX3, the sub-pixel SPX may be connected to the second emission control line EL2 located on the corresponding horizontal line, and may receive the emission control signal EM (also referred to as “second emission control signal”) from the second emission control line EL2.

The sub-pixel SPX may be connected to the data driver 252 through the data line DL. The data driver 252 may output a data voltage Vdata corresponding to the image data of each frame to the data line DL.

When the sub-pixel SPX is the first sub-pixel SPX1, the sub-pixel SPX may be connected to the first data line DLr located in the corresponding pixel column. When the sub-pixel SPX is the second sub-pixel SPX2, the sub-pixel SPX may be connected to the second data line DLg located in the corresponding pixel column. When the sub-pixel SPX is the third sub-pixel SPX3, the sub-pixel SPX may be connected to the third data line DLb located in the corresponding pixel column.

The sub-pixel SPX may be connected to the power supply unit 500 through power lines PL. For example, the sub-pixel SPX may be connected to the power supply unit 500 through a first power line VDL, a second power line VSL, a third power line VIL, a fourth power line VAIL, and a fifth power line VOBL. The power supply unit 500 may supply the first driving voltage VDD, the second driving voltage VSS, the third driving voltage VINT, the fourth driving voltage VAINT, and the fifth driving voltage VOBS to the first power line VDL, the second power line VSL, the third power line VIL, the fourth power line VAIL, and the fifth power line VOBL, respectively. In one or more embodiments, the first driving voltage VDD, the second driving voltage VSS, the third driving voltage VINT, the fourth driving voltage VAINT, and the fifth driving voltage VOBS may be a high potential pixel voltage (e.g., an anode voltage), a low potential pixel voltage (e.g., a cathode voltage or common voltage), a first initialization voltage (e.g., a gate initialization voltage), a second initialization voltage (e.g., an anode initialization voltage), and a bias voltage, respectively.

The pixel circuit PXC may control a driving current Ids supplied to the light-emitting element LE in response to the driving signals (e.g., the write scan signal GW, the initialization scan signal GI, the control scan signal GC, the bias scan signal GB, the emission control signal EM, and the data voltage Vdata) supplied to the sub-pixel SPX. The emission timing and luminance of the light-emitting element LE may be controlled by the pixel circuit PXC.

The pixel circuit PXC may include pixel transistors PXT and a storage capacitor Cst. In one or more embodiments, the pixel circuit PXC may further include a boosting capacitor Cbst.

In one or more embodiments, the pixel transistors PXT may include first to eighth transistors T1 to T8. The first transistor T1 may be a driving transistor of the sub-pixel SPX. The second to eighth transistors T2 to T8 may be switching transistors of the sub-pixel SPX.

In one or more embodiments, the sub-pixel SPX may include different types of pixel transistors PXT. For example, the first, second, fifth, sixth, seventh, and eighth transistors T1, T2, T5, T6, T7, and T8 may be P-type transistors (e.g., P-type polycrystalline silicon transistors including active layers containing polycrystalline silicon), and the third and fourth transistors T3 and T4 may be N-type transistors (e.g., N-type oxide transistors including active layers containing an oxide semiconductor). In one or more embodiments, the active layers of P-type transistors (e.g., the active layers containing polycrystalline silicon) and the active layers of N-type transistors (e.g., the active layers containing an oxide semiconductor) may be located in different layers within the display panel 100 (e.g., a backplane layer of the display panel 100).

The first transistor T1 may be connected between the fifth transistor T5 and the sixth transistor T6. The first transistor T1 may be connected to the first power line VDL via the fifth transistor T5, and may be connected to the light-emitting element LE via the sixth transistor T6. The gate electrode of the first transistor T1 may be connected to a first node N1. The first transistor T1 may control the driving current Ids flowing through the sub-pixel SPX according to the voltage of the first node N1 applied to the gate electrode (for example, a voltage corresponding to the data voltage Vdata).

The second transistor T2 may be connected between the data line DL and the first electrode of the first transistor T1 (e.g., the source electrode of the first transistor T1 connected to the fifth transistor T5). The gate electrode of the second transistor T2 may be connected to the write scan line GWL. The second transistor T2 may be turned on by the write scan signal GW of a gate-on voltage (for example, a low level voltage at which the second transistor T2 can be turned on) supplied from the write scan line GWL. When the second transistor T2 is turned on, the data voltage Vdata supplied from the data line DL may be transmitted to the first electrode (e.g., the source electrode) of the first transistor T1.

The third transistor T3 may be connected between the second electrode of the first transistor T1 (e.g., the drain electrode of the first transistor T1 connected to the sixth transistor T6) and the first node N1. The gate electrode of the third transistor T3 may be connected to the control scan line GCL. The third transistor T3 may be turned on by the control scan signal GC of a gate-on voltage (e.g., a high level voltage at which the third transistor T3 can be turned on) supplied from the control scan line GCL to connect the gate electrode of the first transistor T1 to the second electrode of the first transistor T1. When the third transistor T3 is turned on, the first transistor T1 may be driven as a diode, and a voltage corresponding to the data voltage Vdata may be applied to the first node N1.

The fourth transistor T4 may be connected between the first node N1 and the third power line VIL. The gate electrode of the fourth transistor T4 may be connected to the initialization scan line GIL. The fourth transistor T4 may be turned on by the initialization scan signal GI of a gate-on voltage (e.g., a high level voltage at which the fourth transistor T4 can be turned on) supplied from the initialization scan line GIL to connect the first node N1 to the third power line VIL. When the fourth transistor T4 is turned on, the voltage of the first node N1 may be initialized to the third driving voltage VINT of the third power line VIL.

The fifth transistor T5 may be connected between the first power line VDL and the first electrode of the first transistor T1. The gate electrode of the fifth transistor T5 may be connected to the emission control line EL (e.g., the first emission control line EL1 or the second emission control line EL2 of FIG. 3). The fifth transistor T5 may be turned on by the emission control signal EM of a gate-on voltage (e.g., a low level voltage at which the fifth transistor T5 can be turned on) supplied from the emission control line EL to connect the first electrode of the first transistor T1 to the first power line VDL. When the fifth transistor T5 is turned on, the first power line VDL may be connected to the first electrode of the first transistor T1.

The sixth transistor T6 may be connected between the second electrode of the first transistor T1 and the light-emitting element LE. The gate electrode of the sixth transistor T6 may be connected to the emission control line EL. The sixth transistor T6 may be turned on by the emission control signal EM of a gate-on voltage (e.g., a low level voltage at which the sixth transistor T6 can be turned on) supplied from the emission control line EL to connect the second electrode of the first transistor T1 to the light-emitting element LE.

The seventh transistor T7 may be connected between the first electrode of the light-emitting element LE (e.g., the anode electrode connected to the sixth transistor T6) and the fourth power line VAIL. The gate electrode of the seventh transistor T7 may be connected to the bias scan line GBL. The seventh transistor T7 may be turned on by the bias scan signal GB of a gate-on voltage (e.g., a low level voltage at which the seventh transistor T7 can be turned on) supplied from the bias scan line GBL to connect the first electrode of the light-emitting element LE to the fourth power line VAIL. When the seventh transistor T7 is turned on, the voltage of the first electrode of the light-emitting element LE may be initialized to the fourth driving voltage VAINT of the fourth power line VAIL.

The eighth transistor T8 may be connected between the fifth power line VOBL and the first electrode of the first transistor T1. The gate electrode of the eighth transistor T8 may be connected to the bias scan line GBL. The eighth transistor T8 may be turned on by the bias scan signal GB of a gate-on voltage supplied from the bias scan line GBL to connect the first electrode of the first transistor T1 to the fifth power line VOBL. When the eighth transistor T8 is turned on, the voltage of the first electrode of the first transistor T1 may be initialized to the fifth driving voltage VOBS of the fifth power line VOBL. In one or more embodiments, the fifth driving voltage VOBS may be a bias voltage having a voltage level suitable for compensating the hysteresis characteristics of the first transistor T1.

The storage capacitor Cst may be connected between the first node N1 and the first power line VDL. The storage capacitor Cst may be charged with a voltage corresponding to the data voltage Vdata applied to the first node N1.

The boosting capacitor Cbst may be connected between the first node N1 and the write scan line GWL. The voltage of the first node N1 may be stabilized by the coupling effect of the boosting capacitor Cbst, thereby stabilizing the operation of the first transistor T1. The boosting capacitor Cbst may be formed by a parasitic capacitance formed between the first node N1 and the write scan line GWL, or may be designed separately.

The sub-pixel SPX may emit light during a partial period of each frame period, which corresponds to the on-duty ratio, and may not emit light during the remaining period. The emission period and non-emission period of the sub-pixel SPX may be controlled by the emission control signal EM.

A period during which the fifth transistor T5 and the sixth transistor T6 are turned off (e.g., a period during which the emission control signal EM of a high level is supplied to the sub-pixel SPX) may be a non-emission period of the sub-pixel SPX. The non-emission period of the sub-pixel SPX may include an initialization period for initializing a voltage of a corresponding node (e.g., the first node N1 or the like) of the sub-pixel SPX, and a data write and storage period for charging the storage capacitor Cst with a voltage corresponding to the data voltage Vdata. In one or more embodiments, the initialization scan signal GI, the control scan signal GC, the write scan signal GW, and the bias scan signal GB of a gate-on voltage may be supplied during the non-emission period of the sub-pixel SPX. In one or more embodiments, the initialization scan signal GI, the control scan signal GC, and the bias scan signal GB of the gate-on voltage may be sequentially supplied during the non-emission period of the sub-pixel SPX. The periods in which the initialization scan signal GI and the control scan signal GC of the gate-on voltage are supplied may overlap, but the present disclosure is not limited thereto. The write scan signal GW of the gate-on voltage may be supplied during the period when the control scan signal GC of the gate-on voltage is supplied.

The period during which the fifth transistor T5 and the sixth transistor T6 are turned on (e.g., the period during which the emission control signal EM of a low level is supplied to the sub-pixel SPX) may be an emission period of the sub-pixel SPX. During the emission period of the sub-pixel SPX, the first transistor T1 may supply the driving current Ids corresponding to the voltage of the first node N1 to the light-emitting element LE.

The light-emitting element LE may be connected between the pixel circuit PXC and the second power line VSL. For example, the first electrode (e.g., the anode electrode or pixel electrode) of the light-emitting element LE may be connected to a node between the sixth transistor T6 and the seventh transistor T7, and the second electrode (e.g., the cathode electrode or common electrode) of the light-emitting element LE may be connected to the second power line VSL. The light-emitting element LE may emit light to correspond to the driving current Ids supplied from the pixel circuit PXC.

In one or more embodiments, the sub-pixel SPX may include a single light-emitting element LE, but is not limited thereto. For example, the sub-pixel PX may include a plurality of light-emitting elements LE.

In one or more embodiments, the light-emitting element LE may be a micro light-emitting diode containing an inorganic compound, such as a nitride-based or phosphide-based semiconductor material, but is not limited thereto. For example, the light-emitting element LE may be an organic light-emitting element, a quantum dot light-emitting element, or another type of light-emitting element. In addition, the size or shape of the light-emitting element LE may be different according to the embodiments.

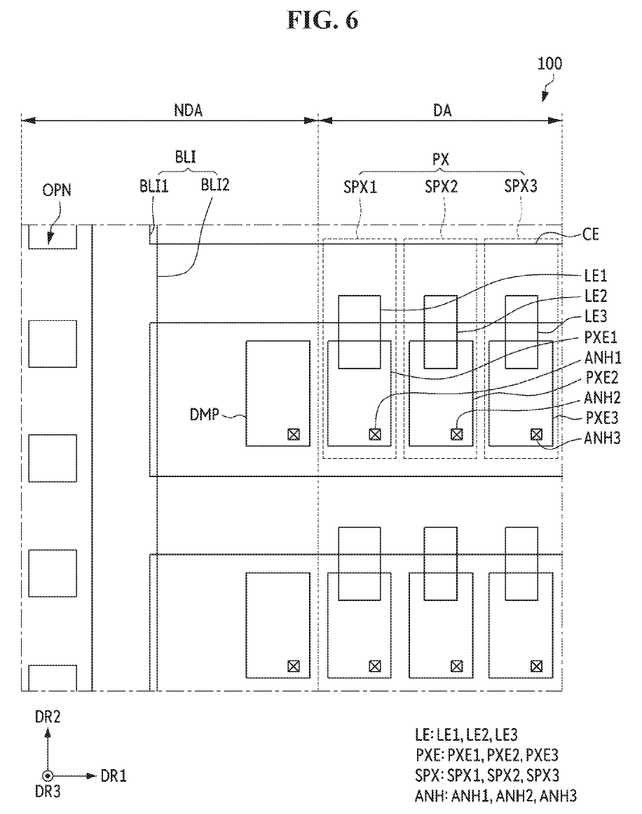

FIG. 6 is a plan view illustrating a display panel according to one or more embodiments. For example, FIG. 6 shows a part of the display area DA where two pixels PX are sequentially located in the second direction DR2, and a part of the non-display area NDA adjacent to a part of the display area DA and where a power bus line BLI is located.

FIG. 6 shows one or more embodiments of a light-emitting element layer including light-emitting elements LE of sub-pixels SPX. The display panel 100 may further include a backplane layer including circuit elements of the sub-pixels SPX (for example, circuit elements included in each of the pixel circuits PXC of the sub-pixels SPX.

Referring to FIG. 6, each of the sub-pixels SPX may include the pixel electrode PXE, and the light-emitting element LE located on the pixel electrode PXE (as used herein, “located on” may mean “above”). In one or more embodiments, when the light-emitting element LE is a micro LED of a flip-chip type or a lateral type, each of the sub-pixels SPX may further include a common electrode CE located on one surface (for example, a bottom surface or a top surface) of the light-emitting element LE together with the pixel electrode PXE. In one or more other embodiments, when the light-emitting element LE is a micro LED of a vertical type, the light-emitting element LE of each of the sub-pixels SPX may be located on the pixel electrode PXE, and the common electrode CE (for example, the common electrode CE located as a common layer in the entire display area DA) may be located on the light-emitting elements LE of the sub-pixels SPX. FIG. 6 shows the display panel 100 including the light-emitting elements LE of a flip-chip type. The pixel electrode PXE may also be referred to as the anode electrode or the first electrode, and the common electrode CE may also be referred to as the cathode electrode or the second electrode.

In one or more embodiments, the sub-pixels SPX of each pixel PX may be arranged in the first direction DR1 and may share one common electrode CE. For example, the common electrode CE may extend in the first direction DR1 in each pixel row (or horizontal line) of the display area DA, and the sub-pixels SPX of the pixels PX located on the corresponding pixel row may share one common electrode CE.

The first sub-pixel SPX1 may include a first pixel electrode PXE1 and the common electrode CE (or a part of the common electrode CE) spaced apart from each other, and a first light-emitting element LE1 located on the first pixel electrode PXE1 and the common electrode CE. The first light-emitting element LE1 may refer to the light-emitting element LE of the first sub-pixel SPX1. The first light-emitting element LE1 may be electrically connected between the first pixel electrode PXE1 and the common electrode CE.

The second sub-pixel SPX2 may include a second pixel electrode PXE2 and the common electrode CE spaced apart from each other, and a second light-emitting element LE2 located on the second pixel electrode PXE2 and the common electrode CE. The second light-emitting element LE2 may refer to the light-emitting element LE of the second sub-pixel SPX2. The second light-emitting element LE2 may be electrically connected between the second pixel electrode PXE2 and the common electrode CE.

The third sub-pixel SPX3 may include a third pixel electrode PXE3 and the common electrode CE spaced apart from each other, and a third light-emitting element LE3 located on the third pixel electrode PXE3 and the common electrode CE. The third light-emitting element LE3 may refer to the light-emitting element LE of the third sub-pixel SPX3. The third light-emitting element LE3 may be electrically connected between the third pixel electrode PXE3 and the common electrode CE.

In one or more embodiments, the first pixel electrode PXE1, the second pixel electrode PXE2, and the third pixel electrode PXE3 of each pixel PX may be arranged in the first direction DR1, and may be spaced apart from the common electrode CE in the second direction DR2. For example, in each pixel PX, the first pixel electrode PXE1, the second pixel electrode PXE2, and the third pixel electrode PXE3 may be arranged sequentially in the first direction DR1. Further, the first pixel electrode PXE1, the second pixel electrode PXE2, and the third pixel electrode PXE3 may face different parts of the common electrode CE in the second direction DR2. In one or more other embodiments, when the sub-pixels SPX include a micro LED of a vertical type, the first pixel electrode PXE1, the second pixel electrode PXE2, and the third pixel electrode PXE3 may face the common electrode CE in the third direction DR3.

The pixel circuit PXC (see FIG. 4) and the pixel electrode PXE of each of the sub-pixels SPX may be electrically connected to each other through an anode contact hole ANH. For example, the first pixel electrode PXE1 of the first sub-pixel SPX1 may be electrically connected to at least one circuit element (for example, the sixth and seventh transistors T6 and T7 of FIG. 4) included in the pixel circuit PXC of the first sub-pixel SPX1 through a first anode contact hole ANH1 and/or at least one connection pattern. Similarly, the second pixel electrode PXE2 of the second sub-pixel SPX2 may be electrically connected to at least one circuit element included in the pixel circuit PXC of the second sub-pixel SPX2 through a second anode contact hole ANH2 and/or at least one connection pattern, and the third pixel electrode PXE3 of the third sub-pixel SPX3 may be electrically connected to at least one circuit element included in the pixel circuit PXC of the third sub-pixel SPX3 through a third anode contact hole ANH3 and/or at least one connection pattern.

The light-emitting elements LE may be located between the respective pixel electrodes PXE and the common electrode CE. For example, the first light-emitting element LE1 may be located on the first pixel electrode PXE1 and the common electrode CE, and a part of the first light-emitting element LE1 may overlap the first pixel electrode PXE1 and another part of the first light-emitting element LE1 may overlap the common electrode CE. The second light-emitting element LE2 may be located on the second pixel electrode PXE2 and the common electrode CE, and a part of the second light-emitting element LE2 may overlap the second pixel electrode PXE2 and another part of the second light-emitting element LE2 may overlap the common electrode CE. The third light-emitting element LE3 may be located on the third pixel electrode PXE3 and the common electrode CE, and a part of the third light-emitting element LE3 may overlap the third pixel electrode PXE3 and another part of the third light-emitting element LE3 may overlap the common electrode CE.

Each of the light-emitting elements LE may emit light of a corresponding color (for example, red light, green light, blue light, or white light). In one or more embodiments, the first light-emitting element LE1, the second light-emitting element LE2, and the third light-emitting element LE3 may emit light of different colors. For example, the first light-emitting element LE1, the second light-emitting element LE2, and the third light-emitting element LE3 may emit light of a first color (for example, red light), light of a second color (for example, green light), and light of a third color (for example, blue light), respectively.

In one or more embodiments, the light-emitting elements LE of at least two sub-pixels SPX may have different respective sizes. For example, the size of the first light-emitting element LE1 may be larger than the size of each of the second light-emitting element LE2 and the third light-emitting element LE3. The sizes of the second light-emitting element LE2 and the third light-emitting element LE3 may be the same or different.

In one or more embodiments, the light-emitting elements LE may have a differentiated or improved/optimized size depending on the luminous efficiency of the light-emitting elements LE or the like. For example, depending on the luminous efficiency of each of the first light-emitting element LE1, the second light-emitting element LE2, and the third light-emitting element LE3, at least two light-emitting elements LE among the first light-emitting element LE1, the second light-emitting element LE2, and the third light-emitting element LE3 may have different sizes. For example, when the luminous efficiency of the first light-emitting element LE1 is less than the luminous efficiency of each of the second light-emitting element LE2 and the third light-emitting element LE3 based on the same size and shape, the size of the first light-emitting element LE1 may be larger than the size of each of the second light-emitting element LE2 and the third light-emitting element LE3. Accordingly, the luminous efficiency of the first light-emitting element LE1 may be improved, and the luminous efficiency deviation of the first light-emitting element LE1, the second light-emitting element LE2, and the third light-emitting element LE3 may be reduced or prevented.

In one or more other embodiments, the first light-emitting element LE1, the second light-emitting element LE2, and the third light-emitting element LE3 may emit light of the same color. In this case, at least one of a color filter or a light conversion layer (for example, light conversion layer including wavelength conversion particles, such as quantum dots or the like) for converting light emitted from the light-emitting element LE of the corresponding sub-pixel SPX to light corresponding to the emission color of the corresponding sub-pixel SPX may be located on at least one light-emitting element LE of the first sub-pixel SPX1, the second sub-pixel SPX2, and the third sub-pixel SPX3. When the first light-emitting element LE1, the second light-emitting element LE2, and the third light-emitting element LE3 emit light of the same color, the first light-emitting element LE1, the second light-emitting element LE2, and the third light-emitting element LE3 may have the same size or different sizes. For example, depending on the light conversion efficiency by the light conversion layer, at least one of the size of the light-emitting elements LE of the sub-pixels SPX or the area of the emission areas EA of the sub-pixels SPX may be differentiated.

The common electrode CE may be electrically connected to the power bus line BLI (for example, the cathode bus line) to which the second driving voltage VSS is applied. In one or more embodiments, the common electrode CE may extend to the non-display area NDA around the display area DA, and may be electrically connected to the power bus line BLI in the non-display area NDA. The common electrode CE may be electrically connected to the power bus line BLI through at least one contact hole and/or connection line, or may be integrally formed with at least a part of the power bus line BLI. For example, the power bus line BLI may include a plurality of wiring layers, and one of the plurality of wiring layers and the common electrode CE may be formed as substantially one pattern.

In one or more embodiments, the second power line VSL (see FIG. 4) to which the second driving voltage VSS is applied may be located also in the display area DA. For example, the second power line VSL intersecting or overlapping the common electrode CE may be located in the backplane layer located under the common electrode CE. In this case, the common electrode CE may be electrically connected to the second power line VSL through at least one contact hole and/or connection line in the display area DA.

The power bus line BLI may be located in the non-display area NDA, and may be located on at least one side of the display area DA. For example, the power bus line BLI may be located on the left side and the right side of the display area DA, and may be further selectively located on at least one of the upper side or the lower side of the display area DA. In FIG. 6, a part of the power bus line BLI located on the left side of the display area DA is illustrated.

The power bus line BLI may be electrically connected to the power supply unit 500 (see FIG. 3). For example, the power bus line BLI may be electrically connected to the power supply unit 500 through at least one pad PD and/or at least one connection line located in the sub-region SBA and/or the non-display area NDA of the main region MA. Accordingly, the second driving voltage VSS outputted from the power supply unit 500 may be applied to the power bus line BLI. The power bus line BLI may form a part of the second power line VSL electrically connected between the power supply unit 500 and the sub-pixels SPX. In addition to the embodiments described above, the connection structure between the common electrode CE and the second power line VSL may be variously changed.

In one or more embodiments, the power bus line BLI may be formed as multiple layers including the first wiring layer BLI1 and the second wiring layer BLI2. The first wiring layer BLI1 and the second wiring layer BLI2 may be electrically connected to each other.

The first wiring layer BLI1 may be located in the same layer as the pixel electrodes PXE and the common electrode CE, and may include a conductive material included in the pixel electrodes PXE and the common electrode CE. In one or more embodiments, the first wiring layer BLI1 may be integrally formed with the common electrode CE. For example, at least one end of the common electrode CE may extend to the non-display area NDA, and may be connected to the first wiring layer BLI1 of the power bus line BLI.

The second wiring layer BLI2 may overlap at least a part of the first wiring layer BLI1. In one or more embodiments, the second wiring layer BLI2 may be located under the first wiring layer BLI1, and may be in contact with the first wiring layer BLI1. For example, at least one insulating layer that covers the end of the second wiring layer BLI2 and the like may be located between the first wiring layer BLI1 and the second wiring layer BLI2, and the at least one insulating layer may be opened in the region where the first wiring layer BLI1 and the second wiring layer BLI2 overlap. In the portion where the at least one insulating layer is opened, the first wiring layer BLI1 and the second wiring layer BLI2 may be in contact with each other and may be electrically connected to each other.

In one or more embodiments, the second wiring layer BLI2 may have a width that is greater than that of the first wiring layer BLI1 in the first direction DR1. For example, the second wiring layer BLI2 may extend further toward the outer edge of the display panel 100 from a portion overlapping the first wiring layer BLI1, and may cover the scan driver (for example, the first scan driver SDC1 and the second scan driver SDC2 of FIGS. 2 and 3). In one or more embodiments, the second wiring layer BLI2 may include a plurality of openings OPN. Accordingly, gas generated by outgassing in the display panel 100 may be appropriately discharged.

In one or more embodiments, dummy patterns DMP may be further located in the non-display area NDA. For example, the dummy patterns DMP may have a shape and/or size corresponding to those of the pixel electrodes PXE, and may be located around the pixel electrodes PXE located at the outermost edge of the display area DA. In one or more embodiments, dummy pixel circuits connected to the respective dummy patterns DMP through respective dummy holes may be located under the dummy patterns DMP. The dummy patterns DMP, and/or the dummy pixel circuits may be omitted.

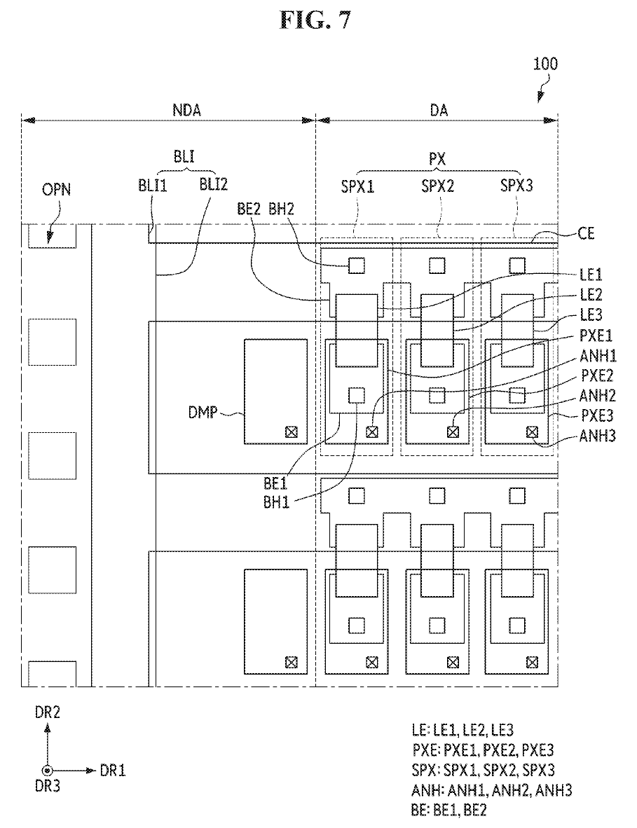

FIG. 7 is a plan view illustrating a display panel according to one or more embodiments. In comparison with FIG. 6, FIG. 7 shows the display panel 100 further including connection electrodes BE. In describing the following embodiments, components substantially identical or similar to those of at least one or more embodiments described above are designated with the same reference numerals, and redundant descriptions will be omitted.

Referring to FIGS. 6 and 7, the display panel 100 may further include the connection electrodes BE located in the sub-pixels SPX. For example, each sub-pixel SPX may include a first connection electrode BE1 located on the pixel electrode PXE, and a second connection electrode BE2 located on the common electrode CE.

The first connection electrode BE1 may connect the pixel electrode PXE to the light-emitting element LE. For example, in each sub-pixel SPX, the first connection electrode BE1 may be electrically connected to the pixel electrode PXE through a first connection hole BH1. The first connection hole BH1 may be an opening formed in an insulating layer or an adhesive layer located between the pixel electrode PXE and the light-emitting element LE. Further, the first connection electrode BE1 may be in contact with a part (for example, a side surface on which the first contact electrode of the light-emitting element LE is located) of the light-emitting element LE located on the pixel electrode PXE and may be electrically connected to the light-emitting element LE. As illustrated in FIG. 7, the first connection electrodes BE1 may contact only one portion of the side of the light-emitting element LE, but the present disclosure is not limited thereto. For example, in one or more other embodiments, the first connection electrode BE1 may be located on one portion of the top surface of the light-emitting element LE.

The second connection electrode BE2 may connect the common electrode CE to the light-emitting element LE. For example, in each sub-pixel SPX, the second connection electrode BE2 may be electrically connected to the common electrode CE through a second connection hole BH2. The second connection hole BH2 may be an opening formed in an insulating layer or an adhesive layer located between the common electrode CE and the light-emitting element LE. Further, the second connection electrode BE2 may be in contact with another part (for example, a side surface on which the second contact electrode of the light-emitting element LE is located) of the light-emitting element LE located on the common electrode CE and may be electrically connected to the light-emitting element LE. As illustrated in FIG. 7, the second connection electrodes BE2 may be in contact with only one portion of the side surface of the light-emitting element LE, but the embodiments are not limited thereto. For example, in one or more other embodiments, the second connection electrode BE2 may be located in one portion of the top surface of the light-emitting element LE. However, the first connection electrode BE1 and the second connection electrode BE2 may be separated from each other. In one or more embodiments, the second connection electrodes BE2 of the sub-pixels SPX located in one pixel PC or one horizontal line may be integrally formed to form substantially one pattern, but the present embodiments are not limited thereto.

Although the embodiments, in which the first connection electrode BE1 and the pixel electrode PXE are electrically connected through the first connection hole BH1, and in which the second connection electrode BE2 and the common electrode CE are electrically connected through the second connection hole BH2, are illustrated in FIG. 7, the disclosure is not limited thereto. For example, in one or more other embodiments, the insulating layer or the adhesive layer on the pixel electrode PXE and the common electrode CE may partially cover the pixel electrode PXE and the common electrode CE only under the light-emitting element LE and/or directly around the light-emitting element LE, and may not be located on other parts of the pixel electrode PXE and the common electrode CE. In this case, the first connection hole BH1 and the second connection hole BH2 may be omitted, and the first connection electrode BE1 and the second connection electrode BE2 may be directly located on other parts of the pixel electrode PXE and the common electrode CE, respectively.

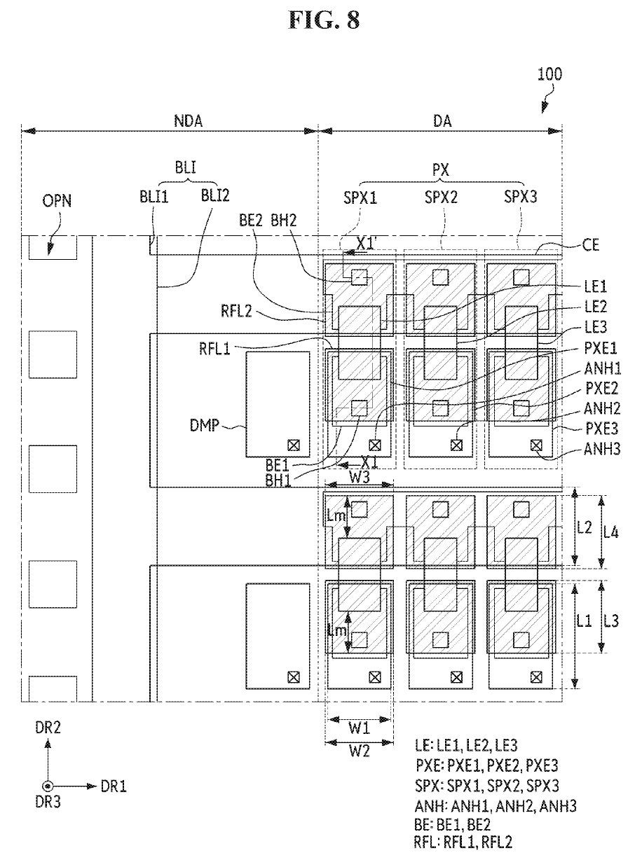

FIG. 8 is a plan view illustrating a display panel according to one or more embodiments. In comparison with FIG. 7, FIG. 8 shows the display panel 100 further including a reflective layer RFL.

Referring to FIGS. 6 to 8, the display panel 100 may further include the reflective layer RFL located in the sub-pixels SPX. The reflective layer RFL may cover at least one portion of each of the pixel electrode PXE and the common electrode CE. For example, the reflective layer RFL may include a first reflective layer RFL1 and a second reflective layer RFL2 respectively located on the pixel electrode PXE and the common electrode CE of each of the sub-pixels SPX.

The first reflective layer RFL1 may cover at least one portion of the pixel electrode PXE. For example, the first reflective layer RFL1 may be located on one portion of the pixel electrode PXE including an end portion overlapping the light-emitting element LE.

The second reflective layer RFL2 may cover at least one portion of the common electrode CE. For example, the second reflective layer RFL2 may be located on one portion of the common electrode CE including an end portion overlapping the light-emitting element LE. The end portion of the common electrode CE overlapping the light-emitting element LE may be an end portion adjacent to the pixel electrode PXE. The end portion of the first reflective layer RFL1 overlapping the light-emitting element LE and the end portion of the second reflective layer RFL2 overlapping the light-emitting element LE may face each other.

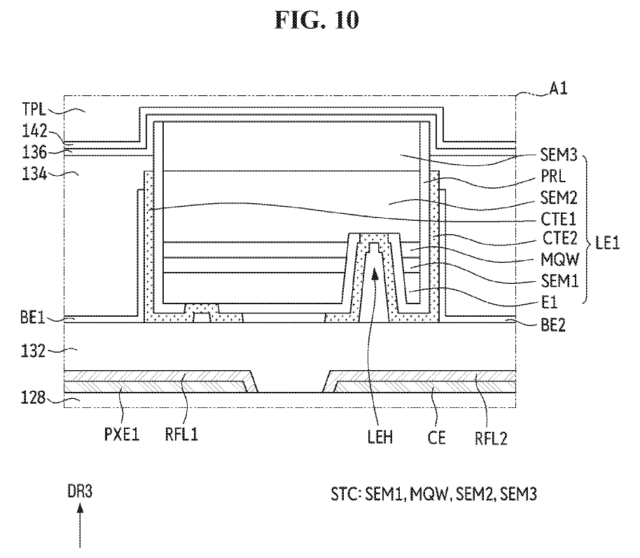

The light-emitting element LE of each of the sub-pixels SPX may be located on the first reflective layer RFL1 and the second reflective layer RFL2. For example, one portion of the light-emitting element LE may be located on the first reflective layer RFL1, and the other portion of the light-emitting element LE may be located on the second reflective layer RFL2. In one or more embodiments, the first connection electrode BE1 and the second connection electrode BE2 may be located on the first reflective layer RFL1 and the second reflective layer RFL2, respectively. The first connection electrode BE1 may connect the pixel electrode PXE or the first reflective layer RFL1 and one portion (for example, a first contact electrode CTE1 of FIG. 10) of the light-emitting element LE, and the second connection electrode BE2 may connect the common electrode CE or the second reflective layer RFL2 and the other portion (for example, a second contact electrode CTE2 of FIG. 10) of light-emitting element LE.

In one or more embodiments, each of the first reflective layer RFL1 and the second reflective layer RFL2 may be a conductive layer of a single layer or multi-layers including a conductive material. In addition, the first reflective layer RFL1 and the second reflective layer RFL2 may be separated from each other. The pixel electrode PXE may be electrically connected to one portion of the light-emitting element LE through the first connection electrode BE1, and the common electrode CE may be electrically connected to the other portion of the light-emitting element LE through the second connection electrode BE2. In a case where the first reflective layer RFL1 and the second reflective layer RFL2 have conductivity, the first reflective layer RFL1 may refer to as the “first reflective electrode,” and the second reflective layer RFL2 may refer to as the “second reflective electrode.”

The first reflective layer RFL1 and the second reflective layer RFL2 may have a material with high reflectivity for light emitted from the light-emitting element LE. For example, the first reflective layer RFL1 and the second reflective layer RFL2 may include silver (Ag), or aluminum (Al), or other metal with high light reflectivity. In one or more embodiments, the first reflective layer RFL1 and the second reflective layer RFL2 may be formed of a three-layer structure (ITO/Ag/ITO) of indium tin oxide (ITO), silver (Ag), and indium tin oxide (ITO), but the embodiments are not limited thereto. In addition, each of the first reflective layer RFL1 and the second reflective layer RFL2 may be formed as a single layer or multi-layers.

In one or more embodiments, the first reflective layer RFL1 and the second reflective layer RFL2 of each sub-pixel SPX may have a shape and/or size corresponding to each other. For example, the first reflective layer RFL1 and the second reflective layer RFL2 of each sub-pixel SPX may have substantially the same shape and/or size and may be formed to be symmetrical. In describing the embodiments, the term “substantially identical to one another” may include the meaning of “completely identical,” as well as the meaning of “similar to one another to the extent that they have minute deviations within the allowable error range including the process margin.”

For example, the first reflective layer RFL1 and the second reflective layer RFL2 may have a substantially symmetrical shape (for example, a vertically symmetrical shape as in the plan view of FIG. 8) with respect to the light-emitting element LE of each sub-pixel SPX, or with respect to the axis of symmetry that passes through the center between the pixel electrode PXE and the common electrode CE and may extend in the first direction DR1. As the first reflective layer RFL1 and the second reflective layer RFL2 are formed symmetrically, the light emission characteristics of the sub-pixel SPX may be improved. For example, light emitted from the light-emitting element LE may be more uniformly and/or efficiently reflected by the first reflective layer RFL1 and the second reflective layer RFL2, which are symmetrical to each other, and may be emitted to the upper portion of the sub-pixel SPX.

In one or more embodiments, the first reflective layer RFL1 may have a width W2 (hereinafter, referred to as “second width W2”) that is greater than a width W1 (hereinafter, referred to as “first width W1”) of the pixel electrode PXE in the first direction DR1, and may cover one end of the pixel electrode PXE facing the common electrode CE. In one or more embodiments, the first direction DR1 may be a direction in which one end portion of the pixel electrode PXE facing the common electrode CE and one end portion of the common electrode CE facing the pixel electrode PXE extend. For example, the first reflective layer RFL1 may appropriately cover the top surface and side surface of the pixel electrode PXE at a portion overlapping the light-emitting element LE and at the periphery thereof. In one or more embodiments, the second reflective layer RFL2 may have a width W3 (hereinafter, referred to as “third width W3”) in the first direction DR1 that corresponds to the second width W2 of the first reflective layer RFL1. For example, the second width W2 of the first reflective layer RFL1 and the third width W3 of the second reflective layer RFL2 may be substantially the same. The second reflective layer RFL2 may cover one end portion of the common electrode CE facing the pixel electrode PXE. For example, the second reflective layer RFL2 may appropriately cover a portion overlapping the light-emitting element LE and the top surface and side surface (for example, the side surface facing the pixel electrode PXE) of the common electrode CE at the periphery thereof. Accordingly, the first reflective layer RFL1 and the second reflective layer RFL2 may raise light reflectivity, and may improve light efficiency of the sub-pixel SPX.

In one or more embodiments, the pixel electrode PXE may extend to an area where each anode contact hole ANH is located to stably cover each anode contact hole ANH. Accordingly, a length L1 (hereinafter, referred to as “first length L1”) by which the pixel electrode PXE extends in the second direction DR2 may be the same as or greater than a length L2 (hereinafter, referred to as “second length L2”) by which the common electrode CE extends in the second direction DR2. For example, the first length L1 may be greater than the second length L2.

In one or more embodiments, the light-emitting element area (e.g., light-emitting element bonding area) where the light-emitting element LE is placed may be placed or set to be vertically symmetrical with respect to each of the pixel electrode PXE and the common electrode CE. For example, the shape and/or size of an area where the light-emitting element LE and the pixel electrode PXE are overlapped may be substantially the same as the shape and/or size of an area where the light-emitting element LE and the common electrode CE are overlapped. Accordingly, the light-emitting element LE may be stably placed on the pixel electrode PXE and the common electrode CE.

According to one or more embodiments, in a case where the first reflective layer RFL1 and the second reflective layer RFL2 have vertically symmetrical shapes, each of the first reflective layer RFL1 and the second reflective layer RFL2 may extend from the light-emitting element area toward the outer edge of the sub-pixel SPX in the second direction DR2 (for example, upwardly and downwardly of the light-emitting element area) by substantially the same margin length Lm. Accordingly, a length L3 (hereinafter, referred to as “third length L3”) by which the first reflective layer RFL1 extends in the second direction DR2 may be less than or equal to the first length L1. For example, the third length L3 may be less than the first length L1, and the pixel electrode PXE may not be covered with, or may be exposed by, the first reflective layer RFL1 at an end portion that is distant from the area where the light-emitting element LE is located. In one or more embodiments, the common electrode CE may not be covered by, or may be exposed by, the second reflective layer RFL2 at an end portion that is distant from the area where the light-emitting element LE is located. In a case where the second length L2 is less than the first length L1, the size of the portion of the common electrode CE not covered by the second reflective layer RFL2 may be smaller than the size of the portion of the pixel electrode PXE not covered by the first reflective layer RFL1.

In one or more embodiments, the reflective layer RFL may not be placed in the non-display area NDA. For example, the reflective layer RFL may be placed only within the display area DA where the light-emitting elements LE are located, and may not be placed in the non-display area NDA.

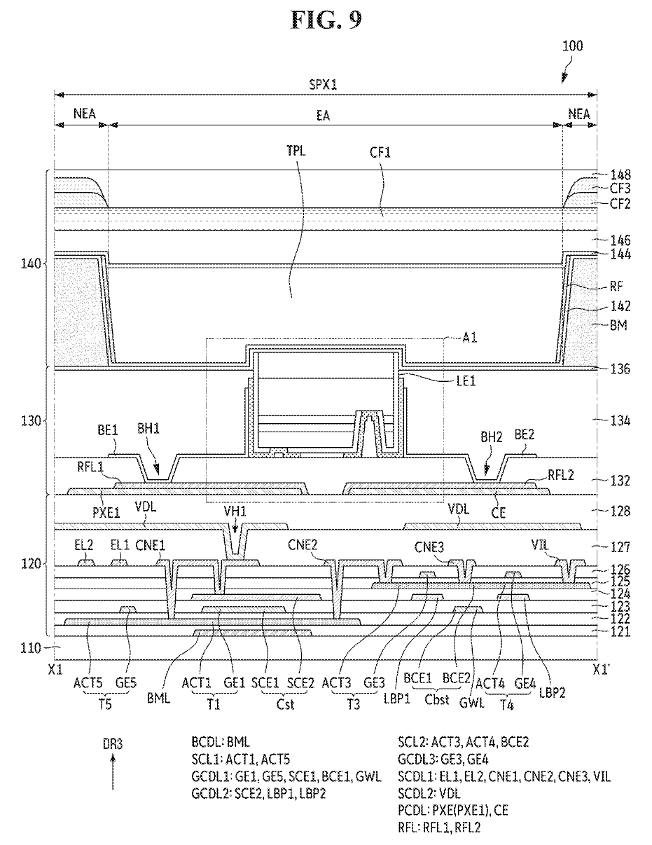

FIG. 9 is a cross-sectional view illustrating a display panel according to one or more embodiments. For example, FIG. 9 shows one or more embodiments of the cross-section of one portion of the display panel 100 taken along the line X1-X1’ of FIG. 8.

FIG. 10 is a cross-sectional view showing area A1 of FIG. 9 in detail. For example, FIG. 10 shows an example of the first light-emitting element LE1 included in the first sub-pixel SPX1 in detail. In one or more embodiments, the first light-emitting element LE1, the second light-emitting element LE2, and the third light-emitting element LE3 of the first sub-pixel SPX1, the second sub-pixel SPX2, and the third sub-pixel SPX3 may have substantially the same or similar cross-sectional structure.

Referring to FIGS. 9 and 10 in addition to FIGS. 1 to 8, the display panel 100 may include a substrate 110, and a backplane layer 120 and a light-emitting element layer 130 located on the substrate 110. In one or more embodiments, the display panel 100 may further include an optical layer 140 located on the light-emitting element layer 130. The backplane layer 120, the light-emitting element layer 130, and the optical layer 140 may be sequentially located on the substrate 110 along the third direction DR3.

The substrate 110 may include an insulating material, such as glass or polymer resin. When the substrate 110 includes polymer resin, it may be a flexible substrate that can be stretched.

The substrate 110 may include the display area DA and the non-display area NDA. The display area DA may include the emission areas EA of the sub-pixels SPX. Each emission area EA may include a light-emitting element area where the light-emitting element LE of each sub-pixel SPX is located.

The backplane layer 120 may include circuit elements included in the pixel circuits PXC of the sub-pixels SPX, and may include wires connected to the sub-pixels SPX. In one or more embodiments, the backplane layer 120 may be formed entirely on one surface of the substrate 110.

The backplane layer 120 may include at least one semiconductor layer, conductive layers, or insulating layers. In one or more embodiments, when the pixel circuits PXC include at least two types of pixel transistors PXT containing different materials, the backplane layer 120 may include a plurality of semiconductor layers.

For example, the backplane layer 120 may include a lower conductive layer BCDL, a barrier layer 121 (or a buffer layer), the first semiconductor layer SCL1 (e.g., a polycrystalline silicon semiconductor layer), a first insulating layer 122 (e.g., a first inorganic insulating layer), the first gate conductive layer GCDL1 (or a first conductive layer), a second insulating layer 123 (e.g., a second inorganic insulating layer), the second gate conductive layer GCDL2 (or a second conductive layer), a third insulating layer 124 (e.g., a third inorganic insulating layer), the second semiconductor layer SCL2 (e.g., an oxide semiconductor layer), a fourth insulating layer 125 (e.g., a fourth inorganic insulating layer), the third gate conductive layer GCDL3 (or a third conductive layer), a fifth insulating layer 126 (e.g., a fifth inorganic insulating layer), the first source-drain conductive layer SCDL1 (or a fourth conductive layer), a sixth insulating layer 127 (e.g., a first organic insulating layer), the second source-drain conductive layer SCDL2 (or a fifth conductive layer), and a seventh insulating layer 128 (e.g., a second organic insulating layer) that are sequentially located on the substrate 110 along the third direction DR3.

The lower conductive layer BCDL may include a lower conductive pattern BML located below the first transistor T1. The lower conductive pattern BML may entirely or partially cover the bottom surface of the first active layer ACT1 included in the first transistor T1. For example, the lower conductive pattern BML may be located below the first active layer ACT1 to overlap a channel region (e.g., a portion of the first active layer ACT1 overlapping the first gate electrode GE1) of the first active layer ACT1. In one or more embodiments, the lower conductive layer BCDL may include a light-blocking material. For example, the lower conductive layer BCDL may include metal, and the lower conductive pattern BML may be formed as a lower metal pattern. Accordingly, light incident on the channel region of the first active layer ACT1 from the bottom of the first active layer ACT1 may be reduced or prevented, and the operating characteristics of the first transistor T1 may be stabilized.

The barrier layer 121 may be located on the lower conductive layer BCDL. The barrier layer 121 may protect the circuit elements of the backplane layer 120 and the light-emitting elements LE on the backplane layer 120 from moisture permeating through the substrate 110 that is susceptible to moisture permeation. In one or more embodiments, the barrier layer 121 may be formed as a plurality of inorganic insulating layers.

The circuit elements of the backplane layer 120 may be located on the barrier layer 121. For example, the pixel transistors PXT, the storage capacitor Cst, and the boosting capacitor Cbst included in the pixel circuit PXC of each of the sub-pixels SPX may be located on the barrier layer 121. Additionally, wires of the backplane layer 120 may be located on the barrier layer 121. For example, signal lines and power lines electrically connected to the sub-pixels SPX may be located on the barrier layer 121.

FIG. 9 shows, as an example of the circuit elements included in the backplane layer 120, the first transistor T1, the third transistor T3, the fourth transistor T4, the fifth transistor T5, the storage capacitor Cst, and the boosting capacitor Cbst that are included in the first sub-pixel SPX1. Further, FIG. 9 shows, as an example of wires included in the backplane layer 120, the write scan line GWL, the first and second emission control lines EL1 and EL2, the first power line VDL, and the third power line VIL. Each of other wires may include at least one wiring layer included in at least one conductive layer included in the backplane layer 120, and may be formed as a single-layer or multi-layer wire.

In one or more embodiments, each of the pixel circuits PXC may include first type transistors and second type transistors. The first type transistors and the second type transistors may be located in different layers within the backplane layer 120. For example, as shown in FIG. 4, each of the pixel circuits PXC may include the first, second, fifth, sixth, seventh, and eighth P-type transistors T1, T2, T5, T6, T7, and T8 and the third and fourth N-type transistors T3 and T4. The active layers included in the first, second, fifth, sixth, seventh, and eighth transistors T1, T2, T5, T6, T7, and T8 and the active layers included in the third and fourth transistors T3 and T4 may be formed in patterns of different semiconductor layers. Further, the gate electrodes included in the first, second, fifth, sixth, seventh, and eighth transistors T1, T2, T5, T6, T7, and T8 and the gate electrodes included in the third and fourth transistors T3 and T4 may be formed in patterns of different conductive layers.

The first semiconductor layer SCL1 (also referred to as “first semiconductor pattern layer”) may be located on the barrier layer 121. The first semiconductor layer SCL1 may include an active layer of each of the first type transistors. For example, in one or more embodiments, the first semiconductor layer SCL1 may include the first active layer ACT1 included in the first transistor T1, a fifth active layer ACT5 included in the fifth transistor T5, and second, sixth, seventh, and eighth active layers included in the second, sixth, seventh, and eighth transistors T2, T6, T7, and T8. In one or more embodiments, the patterns (for example, the first and fifth active layers ACT1 and ACT5 and the second, sixth, seventh, and eighth active layers of each sub-pixel SPX) of the first semiconductor layer SCL1 included in one sub-pixel SPX may be formed integrally, but the present disclosure is not limited thereto.

The patterns of the first semiconductor layer SCL1 may include a first semiconductor material. In one or more embodiments, the first semiconductor material may be polycrystalline silicon (e.g., low temperature polycrystalline silicon), but is not limited thereto. For example, the first semiconductor material may be an oxide semiconductor (e.g., at least one of zinc oxide (ZnO), zinc-tin oxide (ZTO), indium-zinc oxide (IZO), indium oxide (InO), titanium oxide (TiO), indium-gallium oxide (IGO), indium-gallium-zinc oxide (IGZO), indium-gallium-tin oxide (IGTO), indium-zinc-tin oxide (IZTO), or indium-tin-gallium-zinc oxide (ITGZO), or another oxide semiconductor) or monocrystalline silicon.

The first insulating layer 122 may be located on the first semiconductor layer SCL1. The first insulating layer 122 may include at least one insulating material (e.g., silicon nitride (SiNx), silicon oxide (SiOx), silicon oxynitride (SiON), titanium oxide (TiOx), aluminum oxide (AlOx), or another inorganic insulating material) and may be formed as a single layer or multiple layers.

The first gate conductive layer GCDL1 may be located on the first insulating layer 122. The first gate conductive layer GCDL1 may include a gate electrode of each of the first type transistors. For example, the first gate conductive layer GCDL1 may include the first gate electrode GE1 included in the first transistor T1, a fifth gate electrode GE5 included in the fifth transistor T5, and second, sixth, seventh, and eighth gate electrodes included in the second, sixth, seventh, and eighth transistors T2, T6, T7, and T8, in one or more embodiments.

The first gate conductive layer GCDL1 may further include at least one conductive pattern and/or wire. For example, the first gate conductive layer GCDL1 may further include a first capacitor electrode SCE1 of the storage capacitor Cst, a first electrode BCE1 of the boosting capacitor Cbst, and the write scan line GWL. In one or more embodiments, the first gate electrode GE1 of each pixel circuit PXC and the first capacitor electrode SCE1 of the storage capacitor Cst may be formed integrally, and the first electrode BCE1 of the boosting capacitor Cbst of each pixel circuit PXC and the write scan line GWL connected to the pixel circuit PXC may be formed integrally. In one or more embodiments, the first gate conductive layer GCDL1 may further include the bias scan line GBL of FIG. 4.

The second insulating layer 123 may be located on the first gate conductive layer GCDL1. The second insulating layer 123 may contain at least one insulating material (e.g., an inorganic insulating material), and may be formed as a single layer or multiple layers.

The second gate conductive layer GCDL2 may be located on the second insulating layer 123. The second gate conductive layer GCDL2 may include the second capacitor electrode SCE2 of the storage capacitor Cst. The first capacitor electrode SCE1 and the second capacitor electrode SCE2 of the storage capacitor Cst may overlap each other while the second insulating layer 123 is interposed between the first capacitor electrode SCE1 and the second capacitor electrode SCE2.

The second gate conductive layer GCDL2 may further include at least one conductive pattern and/or wire. For example, the second gate conductive layer GCDL2 may further include a first blocking pattern LBP1 and a second blocking pattern LBP2. The first blocking pattern LBP1 and the second blocking pattern LBP2 may be respectively located under a channel region of a third active layer ACT3 (for example, a part of the third active layer ACT3 that overlaps the third gate electrode GE3), and a channel region of a fourth active layer ACT4 (for example, a part of the fourth active layer ACT4 that overlaps the fourth gate electrode GE4). Accordingly, light may be blocked from being incident on the channel regions of the third active layer ACT3 and the fourth active layer ACT4 from the bottom of the third active layer ACT3 and the fourth active layer ACT4, and the operating characteristics of the third transistor T3 and the fourth transistor T4 may be stabilized. In one or more embodiments, the second gate conductive layer GCDL2 may further include the fourth power line VAIL of FIG. 4.

The third insulating layer 124 may be located on the second gate conductive layer GCDL2. The third insulating layer 124 may contain at least one insulating material (e.g., an inorganic insulating material), and may be formed as a single layer or multiple layers.

The second semiconductor layer SCL2 (also referred to as “second semiconductor pattern layer”) may be located on the third insulating layer 124. The second semiconductor layer SCL2 may include the active layer of each of the second type transistors. For example, the second semiconductor layer SCL2 may include the third active layer ACT3 included in the third transistor T3 and the fourth active layer ACT4 included in the fourth transistor T4. In one or more embodiments, the patterns (for example, the third and fourth active layers ACT3 and ACT4 of each sub-pixel SPX) of the second semiconductor layer SCL2 included in one sub-pixel SPX may be formed integrally, but the present disclosure is not limited thereto. In one or more embodiments, the second semiconductor layer SCL2 may further include the second electrode BCE2 of the boosting capacitor Cbst, and the second electrode BCE2 of the boosting capacitor Cbst may be integrally formed with the third and fourth active layers ACT3 and ACT4.

The patterns of the second semiconductor layer SCL2 may include a second semiconductor material. In one or more embodiments, the second semiconductor material may be an oxide semiconductor, but is not limited thereto. For example, the second semiconductor material may be polycrystalline silicon or monocrystalline silicon.

The fourth insulating layer 125 may be located on the second semiconductor layer SCL2. The fourth insulating layer 125 may contain at least one insulating material (e.g., an inorganic insulating material), and may be formed as a single layer or multiple layers.

The third gate conductive layer GCDL3 may be located on the fourth insulating layer 125. The third gate conductive layer GCDL3 may include a gate electrode of each of the second type transistors. For example, the third gate conductive layer GCDL3 may include the third gate electrode GE3 included in the third transistor T3 and the fourth gate electrode GE4 included in the fourth transistor T4. The third gate conductive layer GCDL3 may further include at least one conductive pattern and/or wire. For example, the third gate conductive layer GCDL3 may further include at least one of the initialization scan line GIL, the control scan line GCL, or the fifth power line VOBL.

The fifth insulating layer 126 may be located on the third gate conductive layer GCDL3. The fifth insulating layer 126 may contain at least one insulating material (e.g., an inorganic insulating material), and may be formed as a single layer or multiple layers.

The first source-drain conductive layer SCDL1 may be located on the fifth insulating layer 126. The first source-drain conductive layer SCDL1 may include at least one electrode, a conductive pattern and/or a wire. For example, the first source-drain conductive layer SCDL1 may include first, second, and third connection patterns CNE1, CNE2, and CNE3, the first and second emission control lines EL1 and EL2, and the third power line VIL.

The first connection pattern CNE1 may be electrically connected to the fifth active layer ACT5, to the second capacitor electrode SCE2 of the storage capacitor Cst, and to the first power line VDL through at least one contact hole or via hole. The second connection pattern CNE2 may be electrically connected to the first active layer ACT1 and the third active layer ACT3 through at least one contact hole. The third connection pattern CNE3 may be electrically connected to the third active layer ACT3 and the fourth active layer ACT4 through at least one contact hole. The third connection pattern CNE3 may be electrically connected to the first gate electrode GE1 and the first capacitor electrode SCE1 of the storage capacitor Cst through at least one contact hole in a corresponding area. In one or more embodiments, the first source- drain conductive layer SCDL1 may further include an additional connection pattern for appropriately connecting the circuit elements of each sub-pixel SPX.

The first emission control line EL1 may be electrically connected to the fifth gate electrode GE5 and the sixth gate electrode of the first sub-pixel SPX1 through at least one contact hole in a corresponding area, in one or more embodiments. The second emission control line EL2 may be electrically connected to the fifth and sixth gate electrodes of the second and third sub-pixels SPX2 and SPX3 through at least one contact hole in a corresponding area, in one or more embodiments. The third power line VIL may be electrically connected to the fourth active layer ACT4 through at least one contact hole.

The sixth insulating layer 127 may be located on the first source-drain conductive layer SCDL1. The sixth insulating layer 127 may include at least one insulating material (e.g., acrylic resin, epoxy resin, phenolic resin, polyamide resin, polyimide resin, or another organic insulating material) and may be formed as a single layer or multiple layers.

The second source-drain conductive layer SCDL2 may be located on the sixth insulating layer 127. The second source-drain conductive layer SCDL2 may include at least one electrode, a conductive pattern and/or a wire. For example, the second source-drain conductive layer SCDL2 may include the first power line VDL.

In one or more embodiments, the first power line VDL may extend substantially in the second direction DR2 in the display area DA, and may be commonly connected to the sub-pixels SPX arranged continuously and/or sequentially in the second direction DR2. The first power line VDL illustrated as two separated patterns in FIG. 9 may be substantially one integral wire. The first power line VDL may be electrically connected to the first connection pattern CNE1 through the first via hole VH1 (or contact hole). The first via hole VH1, which is an opening formed in the sixth insulating layer 127 for contact between the first connection pattern CNE1 and the first power line VDL, may be a type of contact hole. In one or more embodiments, the first power line VDL may overlap the channel regions of the first active layer ACT1, the third active layer ACT3, and the fourth active layer ACT4. Accordingly, light incident on the channel regions of the first active layer ACT1, the third active layer ACT3, and the fourth active layer ACT4 from the top of the first active layer ACT1, the third active layer ACT3, and the fourth active layer ACT4 may be reduced or prevented, and the operating characteristics of the first transistor T1, the third transistor T3, and the fourth transistor T4 may be stabilized.

In one or more embodiments, the second source-drain conductive layer SCDL2 may further include an anode connection pattern connected to a pixel electrode PXE of each sub-pixels SPX and the data lines DL of FIGS. 3 and 4. The anode connection pattern of each sub-pixel SPX may be electrically connected between the pixel electrode PXE and the pixel circuit PXC of the corresponding sub-pixel SPX. For example, the anode connection pattern of each sub-pixel SPX may be electrically connected to the sixth and seventh active layers of the corresponding sub-pixel SPX through at least one contact hole and/or at least one connection pattern, and may be electrically connected to the pixel electrode PXE of the corresponding sub-pixel SPX through the anode contact hole ANH of FIG. 8.

The seventh insulating layer 128 may be located on the second source-drain conductive layer SCDL2. The seventh insulating layer 128 may contain at least one insulating material (e.g., an organic insulating material), and may be formed as a single layer or multiple layers.

The patterns included in each of the conductive layers of the backplane layer 120 may contain at least one conductive material. For example, the electrodes, the conductive patterns, and/or the wires included in each of the lower conductive layer BCDL, the first gate conductive layer GCDL1, the second gate conductive layer GCDL2, the third gate conductive layer GCDL3, the first source-drain conductive layer SCDL1 and the second source-drain conductive layer SCDL2 may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), or another metal, an alloy thereof, or another conductive material. In one or more embodiments, the electrodes, the conductive patterns, and/or the wires located in the same conductive layer may be concurrently or substantially simultaneously formed using the same conductive material. At least two conductive layers of the conductive layers of the backplane layer 120 may include the same conductive material or may include different conductive materials.

In one or more embodiments, the patterns included in each of the conductive layers of the backplane layer 120 may have a single-layer or multi-layer structure. For example, each of the electrodes, conductive patterns, and/or wires included in each of the lower conductive layer BCDL, the first gate conductive layer GCDL1, the second gate conductive layer GCDL2, the third gate conductive layer GCDL3, the first source-drain conductive layer SCDL1, and the second source-drain conductive layer SCDL2 may have a single-layer or multilayer structure. At least two of the conductive layers of the backplane layer 120 may have the same cross-sectional structure or different cross-sectional structures.

In one or more embodiments, the patterns of the second source-drain conductive layer SCDL2 may include metal (e.g., at least one of molybdenum (Mo), aluminum (Al), chromium (Cr), gold (Au), titanium (Ti), nickel (Ni), neodymium (Nd), copper (Cu), or another metal, or an alloy thereof), and may have a single-layer or multilayer structure. For example, the electrodes, conductive patterns, and/or wires included in the second source-drain conductive layer SCDL2 may be a low-resistance pattern formed in a three-layer structure (Ti/Al/Ti) of titanium (Ti), aluminum (Al), and titanium (Ti). Alternatively, the patterns of the second source-drain conductive layer SCDL2 may include other low-resistance materials and/or structures. When the resistance of the patterns included in the second source-drain conductive layer SCDL2 is reduced, the resistance of the conductive patterns and/or wires located on the current path through which the driving current of each of the sub-pixels SPX flows may be reduced. Accordingly, the image quality of the display device 1 may become uniform and power consumption may be improved.

The light-emitting element layer 130 may be located on the seventh insulating layer 128. The light-emitting element layer 130 may include the pixel electrodes PXE, the light-emitting elements LE, and the common electrode CE included in the sub-pixels SPX. Additionally, the light-emitting element layer 130 may further include insulating layers. In one or more embodiments, the insulating layers of the light-emitting element layer 130 may include eighth and ninth insulating layers 132 and 134 and a first capping layer 136.

A pixel electrode layer PCDL including the pixel electrodes PXE of the sub-pixels SPX may be located on the seventh insulating layer 128. For example, the pixel electrode layer PCDL may include the first pixel electrode PXE1, the second pixel electrode PXE2, and the third pixel electrode PXE3. In one or more embodiments, the light-emitting element LE may be a flip-chip type micro LED. The flip-chip type micro LED refers to an LED in which first and second contact electrodes CTE1 and CTE2 are formed on one surface (e.g., the bottom surface) of the light-emitting element LE. When the light-emitting element LE is a flip-chip type micro LED, the pixel electrode layer PCDL may further include the common electrode CE. For example, the pixel electrodes PXE and the common electrode CE of the sub-pixels SPX may be located in the same layer, and may be concurrently or substantially simultaneously formed using the same conductive material. FIG. 9 illustrates the common electrode CE and the first pixel electrode PXE1 of the first sub-pixel SPX1 among the patterns of the pixel electrode layer PCDL.

The first pixel electrode PXE1 of the first sub-pixel SPX1 may be electrically connected to the pixel circuit PXC of the first sub-pixel SPX1 through the first anode contact hole ANH1 of FIG. 8. The second pixel electrode PXE2 of the second sub-pixel SPX2 may be electrically connected to the pixel circuit PXC of the second sub-pixel SPX2 through the second anode contact hole ANH2 of FIG. 8. The third pixel electrode PXE3 of the third sub-pixel SPX3 may be electrically connected to the pixel circuit PXC of the third sub-pixel SPX3 through the third anode contact hole ANH3 of FIG. 8. The pixel circuits PXC of the first sub-pixel SPX1, the second sub-pixel SPX2, and the third sub-pixel SPX3 may control voltages applied to the first pixel electrode PXE1, the second pixel electrode PXE2, and the third pixel electrode PXE3, respectively.

In one or more embodiments, the patterns, (e.g., the pixel electrodes PXE and the common electrode CE) of the pixel electrode layer PCDL may include the same conductive material. In one or more embodiments, the patterns of the pixel electrode layer PCDL may include a metal (for example, at least one of molybdenum (Mo), aluminum (Al), chromium (Cr), gold (Au), titanium (Ti), nickel (Ni), neodymium (Nd), copper (Cu), or other metals, or an alloy thereof), and may have a single-layer or multilayer structure. For example, the patterns of the pixel electrode layer PCDL may be low-resistance patterns formed with a three-layer structure (Ti/Al/Ti) of titanium (Ti), aluminum (Al), and titanium (Ti). Alternatively, the patterns of the pixel electrode layer PCDL may include other low- resistance materials (e.g., copper (Cu)) and/or structures. In case of reducing or minimizing the resistance of the patterns included in the pixel electrode layer SPX, the first driving voltage VDD and the second driving voltage VSS may be stably transmitted to the light-emitting elements LE of the sub-pixels SPX.

The reflective layer RFL may be located on the pixel electrode layer PCDL. For example, the first reflective layer RFL1 may be located on the pixel electrode PXE, and the second reflective layer RFL2 may be located on the common electrode CE.

In one or more embodiments, the reflective layer RFL may be located directly on the pixel electrode layer PCDL. For example, the first reflective layer RFL1 may be located on the pixel electrode PXE to contact the pixel electrode PXE, and the second reflective layer RFL2 may be located on the common electrode CE to contact the common electrode CE. However, the embodiments are not limited thereto. For example, at least one insulating layer (e.g., an organic insulating layer) and/or at least one conductive layer (e.g., a metal layer) and the like may be located between the reflective layer RFL and the pixel electrode layer PCDL.

The reflective layer RFL may include a material with high reflectivity for light emitted from the light-emitting element LE. For example, as described above, the reflective layer RFL may include silver (Ag), or aluminum (Al), or include other metal with high light reflectivity.

In one or more embodiments, the first reflective layer RFL1 and the second reflective layer RFL2 may be formed with an appropriate material, structure, and/or thickness considering the light reflectivity by the first reflective layer RFL1 and the second reflective layer RFL2 and the conductivity and reliability of the first reflective layer RFL1 and the second reflective layer RFL2 and the like. For example, each of the first reflective layer RFL1 and the second reflective layer RFL2 may be formed of a three-layer structure (ITO/Ag/ITO) of indium tin oxide (ITO), silver (Ag), and indium tin oxide (ITO). Accordingly, the light reflectivity, the conductivity, and the reliability of the first reflective layer RFL1 and the second reflective layer RFL2 may be secured.

The eighth insulating layer 132 may be located on the pixel electrode layer PCDL and the reflective layer RFL. The eighth insulating layer 132 may be an adhesive layer that temporarily fixes or adheres the light-emitting elements LE to reduce or prevent the likelihood of the light-emitting elements LE tilting and falling over or tipping over during the process of transferring the light-emitting elements LE to the display panel 100. For example, the eighth insulating layer 132 may be a film for temporarily adhering the light-emitting elements LE onto each of the pixel electrodes PXE and the common electrode CE. To facilitate temporary adhesion, the thickness of the eighth insulating layer 132 may be greater than the thickness of each of the pixel electrodes PXE and the common electrode CE, and may be greater than the thickness of each of the first and second contact electrodes CTE1 and CTE2 of the light-emitting elements LE. The eighth insulating layer 132 may also be referred to as “adhesive layer.”

The eighth insulating layer 132 may cover a part of the first reflective layer RFL1 and a part of the second reflective layer RFL2, and may expose other parts of the first reflective layer RFL1and the second reflective layer RFL2. For example, the eighth insulating layer 132 may cover the first reflective layer RFL1 and the second reflective layer RFL2 overlapping the light-emitting element LE, and may be opened at portions corresponding to the first connection hole BH1 and the second connection hole BH2 to partially expose the top surfaces of the first reflective layer RFL1 and second reflective layer RFL2.

Although it is illustrated in FIG. 9 that the eighth insulating layer 132 is entirely located in the display area DA or in a sub-pixel area, the embodiments are not limited thereto. For example, the eighth insulating layer 132 may be located only on parts of the first reflective layer RFL1 and the second reflective layer RFL2 that overlap the light-emitting elements LE, and may expose other parts of the first reflective layer RFL1 and the second reflective layer RFL2. Alternatively, the eighth insulating layer 132 may be separately located in each of the sub-pixels SPX. The eighth insulating layer 132 may not be located in, or may be omitted from, the non-display area NDA.

The eighth insulating layer 132 may include at least one insulating material, for example, an organic insulating material. For example, the eighth insulating layer 132 may be a photosensitive organic layer, such as a photoresist. Alternatively, the eighth insulating layer 132 may include acryl resin, epoxy resin, phenolic resin, polyamide resin, polyimide resin, or the like.

Although it is illustrated in FIG. 9 that the eighth insulating layer 132 is located with an overall uniform thickness or height, the embodiments are not limited thereto. For example, the eighth insulating layer 132 may have a lower height in portions where the light-emitting elements LE are located than in other portions. For example, the eighth insulating layer 132 may be pressed by the pressure applied during the process of locating the light-emitting elements LE on the eighth insulating layer 132, so that the height or thickness of the eighth insulating layer 132 may be partially reduced.

The light-emitting elements LE may be located on the eighth insulating layer 132. The first light-emitting element LE1 may be located on the first pixel electrode PXE1 of the first sub-pixel SPX1 and the common electrode CE. The second light-emitting element LE2 may be located on the second pixel electrode PXE2 of the second sub-pixel SPX2 and the common electrode CE. The third light-emitting element LE3 may be located on the third pixel electrode PXE3 of the third sub-pixel SPX3 and the common electrode CE.

In one or more embodiments, each of the light-emitting elements LE may be a micro LED including an inorganic material. For example, each of the light-emitting elements LE may include an inorganic material, such as gallium nitride (GaN), and the length in the first direction DR1, the length in the second direction DR2, and the length in the third direction DR3 of each of the light-emitting elements LE may each be several µm to several hundred µm. For example, the length in the first direction DR1, the length in the second direction DR2, and the length in the third direction DR3 of each of the light-emitting elements LE may each be approximately 100 µm or less.

The light-emitting elements LE may be formed by growing on a semiconductor substrate, such as a silicon substrate or sapphire substrate. The light-emitting elements LE may be transferred directly from the semiconductor substrate onto the pixel electrodes PXE and the common electrode CE of the display panel 100. Alternatively, the light-emitting elements LE may be transferred onto the common electrode CE and the pixel electrodes PXE of the display panel 100 through an electrostatic method using an electrostatic head or a stamping method using an elastic polymer material, such as PDMS or silicon as a transfer substrate.

The light-emitting element LE may include a conductive layer E1, a semiconductor stack STC, the first and second contact electrodes CTE1 and CTE2, and a protective film PRL. The semiconductor stack STC may include a first semiconductor layer SEM1, an active layer MQW (e.g., light-emitting layer), and a second semiconductor layer SEM2 sequentially arranged in the third direction DR3. In one or more embodiments, the semiconductor stack STC may further include a third semiconductor layer SEM3 located on the second semiconductor layer SEM2.

The conductive layer E1 may be located on the bottom surface of the first semiconductor layer SEM1. FIG. 10 illustrates that the conductive layer E1 covers the entire bottom surface of the first semiconductor layer SEM1, but the embodiments are not limited thereto. For example, the conductive layer E1 may be located on a portion of the bottom surface of the first semiconductor layer SEM1. The conductive layer E1 may include one of molybdenum (Mo), aluminum (Al), chromium (Cr), gold (Au), titanium (Ti), nickel (Ni), neodymium (Nd), or copper (Cu), or a transparent conductive material, such as metal oxide.

The first semiconductor layer SEM1 may be located on the conductive layer E1. The first semiconductor layer SEM1 may include a semiconductor material layer doped with a first conductivity type dopant, such as magnesium (Mg), zinc (Zn), calcium (Ca), strontium (Sr), or barium (Ba), for example, gallium nitride (GaN).

The active layer MQW may be located on the first semiconductor layer SEM1. The active layer MQW may include the same semiconductor material as the first semiconductor layer SEM1 and the second semiconductor layer SEM2. For example, when the first semiconductor layer SEM1 and the second semiconductor layer SEM2 include gallium nitride (GaN), the active layer MQW may also include gallium nitride (GaN). For example, the active layer MQW may include at least one of gallium nitride (GaN), indium gallium nitride (InGaN), or aluminum gallium nitride (AlGaN). The active layer MQW may emit light by recombination of electron-hole pairs according to an electrical signal applied through the first semiconductor layer SEM1 and the second semiconductor layer SEM2. The active layer MQW may include a material having a single or multiple quantum well structure. When the active layer MQW contains a material having a multiple quantum well structure, the active layer MQW may have the structure in which a plurality of well layers and barrier layers are alternately stacked. At this time, the well layer may include InGaN, and the barrier layer may include GaN or AlGaN, but the present disclosure is not limited thereto. Alternatively, the active layer MQW may have a structure in which semiconductor materials having large band gap energy and semiconductor materials having small band gap energy are alternately stacked, and may include other Group III to Group V semiconductor materials according to the wavelength band of the emitted light.

When the active layer MQW includes indium gallium nitride (InGaN), the color of emitted light may vary depending on the content of indium (In). For example, as the content of indium (In) increases, the wavelength band of the light emitted by the active layer MQW may shift to the red wavelength band, and as the content of indium (In) decreases, the wavelength band of the light emitted by the active layer MQW may shift to the blue wavelength band.

The second semiconductor layer SEM2 may be located on the active layer MQW. The second semiconductor layer SEM2 may be a semiconductor material layer doped with a second conductivity type dopant, such as silicon (Si), germanium (Ge), or tin (Sn), for example, gallium nitride (GaN).

The third semiconductor layer SEM3 may be located on the second semiconductor layer SEM2. The third semiconductor layer SEM3 may be a semiconductor material layer having an n-type dopant lower than a selected critical value, and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), or indium nitride (InN) having an n-type dopant lower than a selected threshold value.

An electron-blocking layer may be located between the first semiconductor layer SEM1 and the active layer MQW. The electron-blocking layer may be a layer for suppressing, reducing, or preventing too many electrons from flowing into the active layer MQW. For example, the electron-blocking layer may be AlGaN or p-AlGaN doped with p-type Mg. The electron-blocking layer may be omitted in one or more embodiments.

A superlattice layer may be located between the active layer MQW and the second semiconductor layer SEM2. The superlattice layer may be a layer for relieving stress between the second semiconductor layer SEM2 and the active layer MQW. For example, the superlattice layer may include InGaN or GaN. The superlattice layer may be omitted.

The protective film PRL may be located on the side surface of the first semiconductor layer SEM1, the side surface of the active layer MQW, and the side surface of the second semiconductor layer SEM2. The protective film PRL may be a film for protecting the side surface of the light-emitting element LE. The protective film PRL may include an inorganic material, for example, silicon nitride (SiNx), silicon oxide (SiOx), silicon oxynitride (SiON), titanium oxide (TiOx), aluminum oxide (AlOx), or another inorganic insulating material.

In FIGS. 9 and 10, it is depicted that the protective film PRL is located on the side surfaces of the first semiconductor layer SEM1, the side surfaces of the active layer MQW, and the side surfaces of the second semiconductor layer SEM2 of the semiconductor stack STC and not located on the side surfaces of the third semiconductor layer SEM3, but the embodiments are not limited thereto. For example, the protective film PRL may be located on the side surfaces of the first semiconductor layer SEM1, the side surfaces of the active layer MQW, the side surfaces of the second semiconductor layer SEM2, and the side surfaces of the third semiconductor layer SEM3.

A hole LEH, which penetrates the conductive layer E1, the first semiconductor layer SEM1, and the active layer MQW of the light-emitting element LE to expose the second semiconductor layer SEM2, may be formed. The hole LEH may have a circular planar shape, but the shape of the hole LEH is not limited thereto. For example, the hole LEH may have a planar shape, such as an elliptical shape or a polygonal shape, such as a quadrilateral shape.

The protective film PRL may be located on the sidewall of the conductive layer E1 exposed in the hole LEH, the sidewall of the first semiconductor layer SEM1, and the sidewall of the active layer MQW. The protective film PRL may not cover the second semiconductor layer SEM2 at the hole LEH. Accordingly, the second semiconductor layer SEM2 may be exposed without being covered by the protective film PRL.

The first contact electrode CTE1 may be located on at least one side surface of the semiconductor stack STC and at least one side surface and the bottom surface of the conductive layer E1. The first contact electrode CTE1 may be located on the bottom surface of the conductive layer E1 exposed without being covered by the protective film PRL. Accordingly, the first contact electrode CTE1 may be electrically connected to the conductive layer E1.

The second contact electrode CTE2 may be located on at least one side surface of the semiconductor stack STC and at least one side surface and the bottom surface of the conductive layer E1. At this time, the first contact electrode CTE1 may be located on the first side surface of the semiconductor stack STC and the first side surface of the conductive layer E1, while the second contact electrode CTE2 may be located on the second side surface of the semiconductor stack STC and the second side surface of the conductive layer E1.

The second contact electrode CTE2 may be located on the protective film PRL located in the hole LEH and the second semiconductor layer SEM2 exposed without being covered by the protective film PRL in the hole LEH. Accordingly, the second contact electrode CTE2 may be electrically connected to the second semiconductor layer SEM2 in the hole LEH.

In FIGS. 9 and 10, it is shown that the first contact electrode CTE1 and the second contact electrode CTE2 of each of the light-emitting elements LE are located on the eighth insulating layer 132, but the embodiments are not limited thereto. For example, the eighth insulating layer 132 may be located on a portion of the bottom surface and the side surface of the first contact electrode CTE1 of each of the light-emitting element LE and a portion of the bottom surface and the side surface of the second contact electrode CTE2. Alternatively, the eighth insulating layer 132 may be located on the side surfaces of a conductive layer E1 of each of the light-emitting elements LE. Alternatively, the eighth insulating layer 132 may be located on the side surfaces of the first semiconductor layer SEM1, the side surfaces of the active layer MQW, and the side surfaces of the second semiconductor layer SEM2 of each of the light-emitting elements LE. In this case, the eighth insulating layer 132 may be located on a portion of each of the side surfaces of the second semiconductor layer SEM2.

In one or more embodiments, each of the first contact electrode CTE1 and the second contact electrode CTE2 may be located on three side surfaces of the semiconductor stack STC. For example, when the semiconductor stack STC includes first to fourth side surfaces, the first contact electrode CTE1 may be located on the first side surface, the second side surface, and the third side surface, and the second contact electrode CTE2 may be located on the second side surface, the third side surface, and the fourth side surface.

Each of the first contact electrode CTE1 and the second contact electrode CTE2 may include at least one conductive material, for example, one of molybdenum (Mo), aluminum (Al), chromium (Cr), gold (Au), titanium (Ti), nickel (Ni), neodymium (Nd), or copper (Cu). In one or more embodiments, to increase the reflectivity, the first contact electrode CTE1 and the second contact electrode CTE2 may be formed in a two-layer structure (Cr/Au) of chromium (Cr) and gold (Au), a three-layer structure (Ti/Al/Ti) of titanium (Ti), aluminum (Al), and titanium (Ti), or a three-layer structure (ITO/Ag/ITO) of indium tin oxide (ITO), silver (Ag), and indium-tin oxide (ITO).

When each of the first contact electrode CTE1 and the second contact electrode CTE2 includes metal having high reflectivity, light emitted from the active layer MQW of the light-emitting element LE, which propagates in the lateral direction of the light-emitting element LE, may be reflected by the first contact electrode CTE1 and the second contact electrode CTE2, and may be emitted to the top surface of the light-emitting element LE. Accordingly, because light loss from the light-emitting element LE may be reduced, the light efficiency of the light-emitting element LE may be increased. To increase the light efficiency of the light-emitting element LE, the first contact electrode CTE1 and the second contact electrode CTE2 may be located to cover most of the side surface of the semiconductor stack STC.

The first contact electrode CTE1 may be in contact with the first connection electrode BE1 on the first reflective layer RFL1. The second contact electrode CTE2 may be in contact with the second connection electrode BE2 on the second reflective layer RFL2.

The first connection electrode BE1 and the second connection electrode BE2 may be located on the eighth insulating layer 132.

The first connection electrode BE1 connects the first contact electrode CTE1 of the light-emitting element LE to the pixel electrode PXE. For example, the first connection electrode BE1 of the first sub-pixel SPX1 may connect the first contact electrode CTE1 of the first light-emitting element LE1 and the first pixel electrode PXE1. The first connection electrode BE1 of the second sub-pixel SPX2 may connect the first contact electrode CTE1 of the second light-emitting element LE2 to the second pixel electrode PXE2. The first connection electrode BE1 of the third sub-pixel SPX3 may connect the first contact electrode CTE1 of the third light-emitting element LE3 to the third pixel electrode PXE3.

In one or more embodiments, the first connection electrode BE1 may be in contact with a part of the light-emitting element LE on a part of the first reflective layer RFL1 and the eighth insulating layer 132, and may be in contact with the first reflective layer RFL1 on another part of the first reflective layer RFL1. For example, the first connection electrode BE1 may be in contact with and/or connected to the first reflective layer RFL1 through the first connection hole BH1 penetrating the eighth insulating layer 132, and may be electrically connected to each of the pixel electrodes PXE through the first reflective layer RFL1. In one or more other embodiments, in a case where the eighth insulating layer 132 is located only on one portion of the first reflective layer RFL1 overlapping the light-emitting element LE, the first connection hole BH1 may not be necessary (e.g., may be omitted). For example, the first connection electrode BE1 may be directly located on the first reflective layer RFL1 (or the pixel electrode PXE) exposed at the periphery of the light-emitting element LE.

The second connection electrode BE2 connects the second contact electrode CTE2 of the light-emitting element LE to the common electrode CE. For example, the second connection electrode BE2 of the first sub-pixel SPX1 may connect the second contact electrode CTE2 of the first light-emitting element LE1 and the common electrode CE. The second connection electrode BE2 of the second sub-pixel SPX2 may connect the second contact electrode CTE2 of the second light-emitting element LE2 to the common electrode CE. The second connection electrode BE2 of the third sub-pixel SPX3 may connect the second contact electrode CTE2 of the third light-emitting element LE3 to the common electrode CE.

In one or more embodiments, the second connection electrode BE2 may be in contact with a part of the light-emitting element LE on a part of the second reflective layer RFL2 and the eighth insulating layer 132, and may be in contact with the second reflective layer RFL2 on another part of the second reflective layer RFL2. For example, the second connection electrode BE2 may be in contact with and/or connected to the second reflective layer RFL2 through the second connection hole BH2 penetrating the eighth insulating layer 132, and may be electrically connected to the common electrode CE through the second reflective layer RFL2. In one or more other embodiments, in a case where the eighth insulating layer 132 is located only on one portion of the second reflective layer RFL2 overlapping the light-emitting element LE, the second connection hole BH2 may not be necessary. For example, the second connection electrode BE2 may be directly located on the second reflective layer RFL2 (or the common electrode CE) exposed at the periphery of the light-emitting element LE.

Each of the first connection electrode BE1 and the second connection electrode BE2 may include at least one conductive material, for example, one of molybdenum (Mo), aluminum (Al), chromium (Cr), gold (Au), titanium (Ti), nickel (Ni), neodymium (Nd), or copper (Cu). Alternatively, each of the first connection electrode BE1 and the second connection electrode BE2 may include a transparent conductive material (for example, a transparent conductive oxide (TCO)), such as indium tin oxide (ITO) or indium zinc oxide (IZO).

The conductive layer E1 of the light-emitting element LE may be in contact with and/or connected to the first contact electrode CTE1, and may be electrically connected to the first connection electrode BE1 through the first contact electrode CTE1. The second semiconductor layer SEM2 of the light-emitting element LE may be in contact with and/or connected to the second contact electrode CTE2 formed in the hole LEH, and may be electrically connected to the second connection electrode BE2 through the second contact electrode CTE2.

The ninth insulating layer 134 may be located on the eighth insulating layer 132. In one or more embodiments, the ninth insulating layer 134 may be formed to have a height that is less than or equal to the height of the light-emitting elements LE, and may partially or entirely cover the side surfaces of the light-emitting elements LE. The top surface of each of the light-emitting elements LE may be exposed without being covered by the ninth insulating layer 134.

Further, the ninth insulating layer 134 may cover at least a part of the first and/or second connection electrodes BE1 and/or BE2. For example, as illustrated in FIG. 9, the ninth insulating layer 134 may be formed to have a height greater than or equal to the maximum height of the first and second connection electrodes BE1 and BE2 to completely cover the first and second connection electrodes BE1 and BE2, but the embodiments are not limited thereto.

The ninth insulating layer 134 may include at least one insulating material, for example, an organic insulating material. For example, the ninth insulating layer 134 may be formed as an organic insulating layer, such as acryl resin, epoxy resin, phenolic resin, polyamide resin, polyimide resin and the like. The ninth insulating layer 134 may be formed as a single layer or multiple layers. The ninth insulating layer 134 may flatten the stepped portion caused by the light-emitting elements LE.

The first capping layer 136 may be located on the light-emitting elements LE and the ninth insulating layer 134. The first capping layer 136 may include at least one insulating material, for example, an inorganic insulating material.

The optical layer 140 may be located on the first capping layer 136. The optical layer 140 may include a light-transmitting layer TPL located in the emission areas EA of the sub-pixels SPX, a light-blocking layer BM located in the non-emission area NEA surrounding the emission areas EA of the sub-pixels SPX, and color filters (for example, first, second, and third color filters CF1, CF2, and CF3) corresponding to the emission color of each of the sub-pixels SPX.

Although the structure in which the light-blocking layer BM, the second capping layer 142, and the reflective film RF are located on the first capping layer 136, and the light-transmitting layer TPL and a third capping layer 144 are located on the second capping layer 142 and the reflective film RF is illustrated in FIG. 9, the embodiments are not limited thereto. For example, the arrangement order and/or shape of the light-blocking layer BM, the reflective film RF, and the light-transmitting layer TPL may vary depending on embodiments.

The light-blocking layer BM may be located on the first capping layer 136. The light-blocking layer BM may partition the emission area EA and the non-emission area NEA. The light-blocking layer BM may include a light-blocking material, such as an organic black pigment or an inorganic black pigment, such as carbon black or the like. The light-blocking layer BM may include an organic film, such as acryl resin, epoxy resin, phenolic resin, polyamide resin, polyimide resin and the like, but is not limited thereto.

The second capping layer 142 may be located on the first capping layer 136 and the light-blocking layer BM. The second capping layer 142 may include at least one insulating material, for example, an inorganic insulating material.

The reflective film RF may be located on the light-blocking layer BM. For example, the reflective film RF may be located on a part of the second capping layer 142 that covers the side surface of the light-blocking layer BM. The reflective film RF may reflect light propagating in the lateral direction from the light-transmitting layer TPL. The reflective film RF may include a material having high light reflectivity, for example, a metal, such as aluminum (Al). Alternatively, the reflective film RF may be formed as a distributed Bragg reflector including inorganic films (for example, silicon nitride (SiNₓ), silicon nitride oxide (SiON), silicon oxide (SiOₓ), titanium oxide (TiOₓ), or aluminum oxide (AlOₓ)) having different respective refractive indices and being alternately arranged.

The light-transmitting layer TPL may be located in each emission area EA and surrounded by the light-blocking layer BM. In one or more embodiments, the light- transmitting layer TPL may include a substantially transparent organic material. For example, the light-transmitting layer TPL may be a light-transmitting organic film including epoxy resin, acrylic resin, cardo resin, or imide resin.

In one or more embodiments, the light-emitting element LE may emit light of a color corresponding to the emission color of each sub-pixel SPX, and the light-transmitting layer TPL may transmit the light emitted from the light-emitting element LE. When the sub-pixels SPX include the light-emitting elements LE that emit light corresponding to each emission color, the light emitted from the light-emitting elements LE may be utilized more efficiently. For example, it is possible to reduce or prevent a decrease in the light efficiency of the sub-pixels SPX due to light conversion. In addition, the color purity of light emitted from the sub-pixels SPX may be increased, and the color reproducibility of the sub-pixels SPX may be increased.

In one or more other embodiments, the light-emitting element LE of at least one sub-pixel SPX may emit light of a color that is different from the emission color of the corresponding sub-pixel SPX, and a wavelength conversion layer including wavelength conversion particles may be located on the light-emitting element LE of the at least one sub-pixel SPX. In one or more embodiments, the wavelength conversion layer may include base resin constituting the light-transmitting layer TPL, and wavelength conversion particles (for example, quantum dots, quantum rods, fluorescent materials, or phosphorescent materials) dispersed in the light-transmitting layer TPL. The wavelength conversion layer may convert light emitted from the light-emitting element LE of the corresponding sub-pixel SPX into light of another color. For example, when the first light-emitting element LE1 emits blue light and the first sub-pixel SPX1 is a red sub-pixel that emits red light, the wavelength conversion layer including wavelength conversion particles for converting blue light into red light may be located on the first light-emitting element LE1. When the sub-pixels SPX include light-emitting elements LE that emit light of the same color, the manufacturing efficiency of the light-emitting element layer 130 and the display panel 100 including the same may be increased, and the manufacturing cost may be reduced.

The third capping layer 144 may be located on the second capping layer 142 and the light-transmitting layer TPL. The third capping layer 144 may include at least one insulating material, for example, an inorganic insulating material.

A first overcoat layer 146 may be located on the third capping layer 144. In one or more embodiments, the first overcoat layer 146 may include a light-transmitting organic material (for example, acrylic resin, epoxy resin, phenolic resin, polyamide resin, or polyimide resin), and the top surface of the first overcoat layer 146 may be substantially flat. However, the embodiments are not limited thereto. For example, the first overcoat layer 146 may be an inorganic layer including an inorganic material, and the first overcoat layer 146 may be formed to have a sufficient thickness to include a substantially flat top surface or may be flattened through a separate planarization process. Accordingly, the top surface of the first overcoat layer 146 may be substantially flat.

The color filters of the sub-pixels SPX may be located on the first overcoat layer 146. The color filter for selectively transmitting light corresponding to the color (or wavelength) corresponding to the emission color of the corresponding sub-pixel SPX may be located in the emission area EA of each of the sub-pixels SPX. For example, the first color filter CF1 for selectively transmitting light of the first color may be located in the emission area EA of the first sub-pixel SPX1. In one or more embodiments, the color filters of the sub-pixels SPX may be located to overlap each other in the non-emission area NEA, thereby forming a light-blocking pattern. For example, the first color filter CF1, the second color filter CF2, and the third color filter CF3 respectively located in the first sub-pixel SPX1, the second sub-pixel SPX2, and the third sub-pixel SPX3 may overlap each other in the non-emission area NEA. The second color filter CF2 may selectively transmit light of the second color corresponding to an emission light of the second sub-pixel SPX2, and the third color filter CF3 may selectively transmit light of the third color corresponding to an emission light of the third sub-pixel SPX3.

A second overcoat layer 148 may be located on the first color filter CF1, the second color filter CF2, and the third color filter CF3. In one or more embodiments, the second overcoat layer 148 may include a light-transmitting organic material, and the top surface of the second overcoat layer 148 may be substantially flat. However, the embodiments are not limited thereto. For example, the second overcoat layer 148 may be an inorganic layer including an inorganic material, and the second overcoat layer 148 may be formed to have a sufficient thickness to include a substantially flat top surface or may be flattened through a separate planarization process. Accordingly, the top surface of the second overcoat layer 148 may be substantially flat.

As described above, in the embodiments, the reflective layer RFL may be located under the light-emitting element LE of each of the sub-pixels SPX. For example, the first reflective layer RFL1 and the second reflective layer RFL2 overlapping the other portions of the light-emitting element LE may be respectively located on the pixel electrode PXE and the common electrode CE of each of the sub-pixels SPX.

According to the embodiments, the reflectivity of light emitted from the light-emitting element LE may be increased, and the light efficiency of the sub-pixel SPX may be improved. For example, the light propagating downward toward the first reflective layer RFL1 and a second reflective layer RFL2 among the light emitted from the light-emitting element LE is reflected in an upward direction (for example, toward the front side of the display panel 100) of the sub-pixel SPX by the first reflective layer RFL1 and a second reflective layer RFL2, so that the light output of the sub-pixel SPX may be increased, and the luminance of the sub-pixel SPX may be increased. Accordingly, the light efficiency of the sub-pixels SPX and the display device 1 including them may be improved.

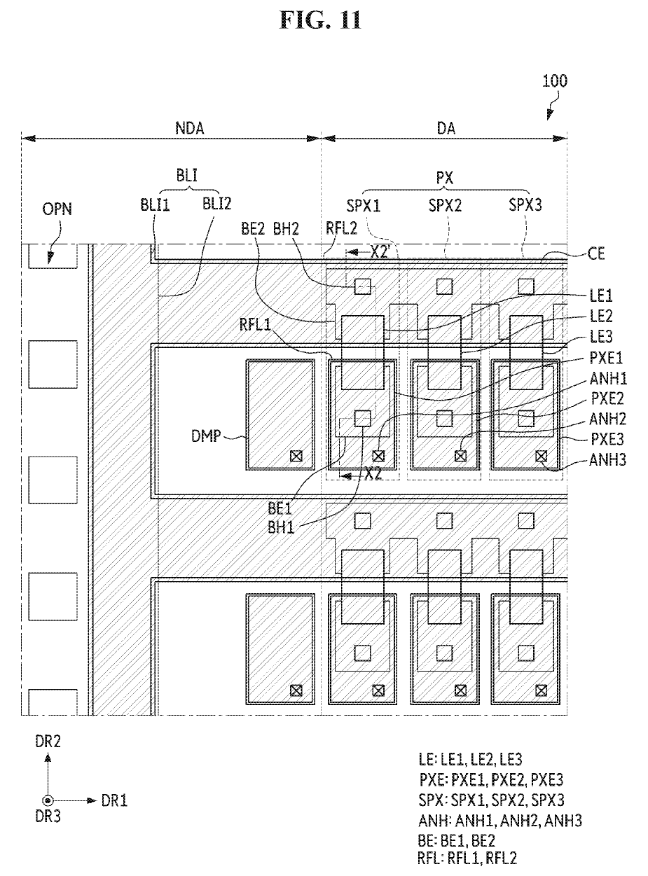

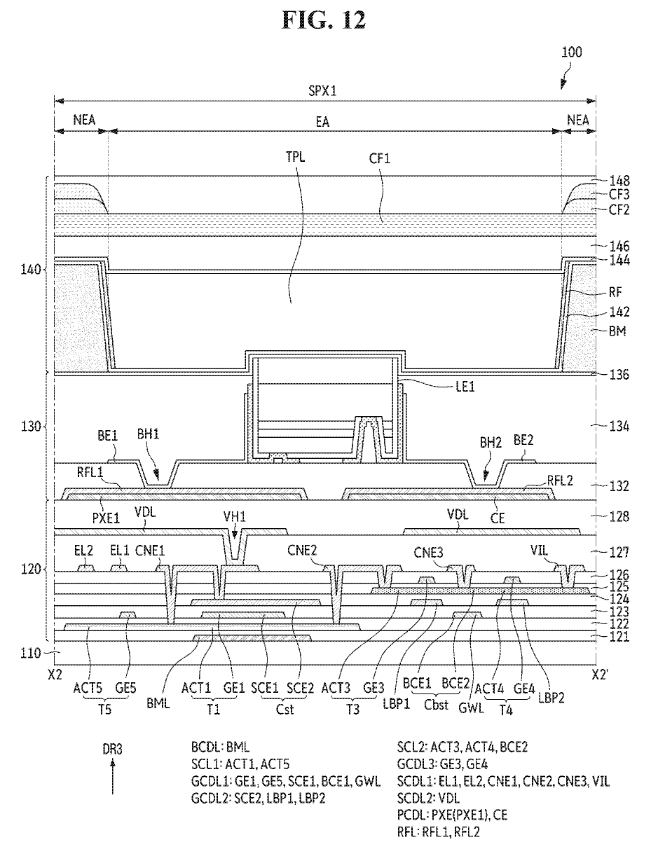

FIG. 11 is a plan view illustrating a display panel according to one or more embodiments. FIG. 12 is a cross-sectional view illustrating a display panel according to one or more embodiments. For example, FIG. 12 shows one or more embodiments of a cross-section with respect to one portion of the display panel 100 taken along the line X2-X2’ of FIG. 11. In comparison with FIGS. 8 and 9, FIGS. 11 and 12 show one or more other embodiments of the reflective layer RFL.

Referring to FIGS. 11 and 12, the reflective layer RFL may entirely cover the pixel electrode PXE and the common electrode CE of each of the sub-pixels SPX. For example, the first reflective layer RFL1 may entirely cover the pixel electrode PXE, and the second reflective layer RFL2 may entirely cover the common electrode CE. For example, the first reflective layer RFL1 may entirely cover the top surface and the side surface of the pixel electrode PXE including the end portion on which the side surface of the pixel electrode PXE is located. In addition, the second reflective layer RFL2 may entirely cover the top surface and the side surface of the common electrode CE including the end portion on which the side surface of the common electrode CE is located.

According to the aforementioned embodiments, damage of the pixel electrodes PXE and the common electrode CE may be reduced or prevented, and the reliability of the display device 1 may be improved. For example, as the reflective layer RFL is formed to entirely cover the pixel electrodes PXE and the common electrode CE, exposure of the pixel electrodes PXE and the common electrode CE to an etchant during the process of forming the reflective layer RFL may be reduced or prevented. For example, while the etching process of the reflective layer (for example, the etching process for patterning the first reflective layer RFL1 and the second reflective layer RFL2 by etching the conductive film) that is executed after forming a film to form the reflective layer RFL is proceeded, the pixel electrodes PXE and the common electrode CE may be entirely covered by the conductive film (or the first reflective layer RFL1 and the second reflective layer RFL2). Accordingly, the conductive film or the first reflective layer RFL1 and the second reflective layer RFL2 formed from the conductive film may function as a capping layer protecting the pixel electrodes PXE and the common electrodes CE, and may reduce or prevent damage to the pixel electrodes PXE and the common electrodes CE in the process of forming the reflective layer RFL or the subsequent process thereafter. For example, even when the pixel electrodes PXE and the common electrode CE are each formed in a three-layer structure (Ti/Al/Ti) of titanium (Ti), aluminum (Al), and titanium (Ti), the pixel electrodes PXE and the common electrode CE are not exposed to an etchant during the etching process for forming the reflective layer RFL. Therefore, a titanium tip (e.g., titanium tip that is formed of titanium (Ti) protruding as aluminum (Al) is consumed by the etchant at the ends (e.g., the side surface) of the pixel electrodes PXE and the common electrode CE) due to the difference in etching rate of the titanium (Ti) and aluminum (Al) or a gap may not occur. Accordingly, the reliability of the sub-pixels SPX and the display device 1 including the sub-pixels SPX may be improved.

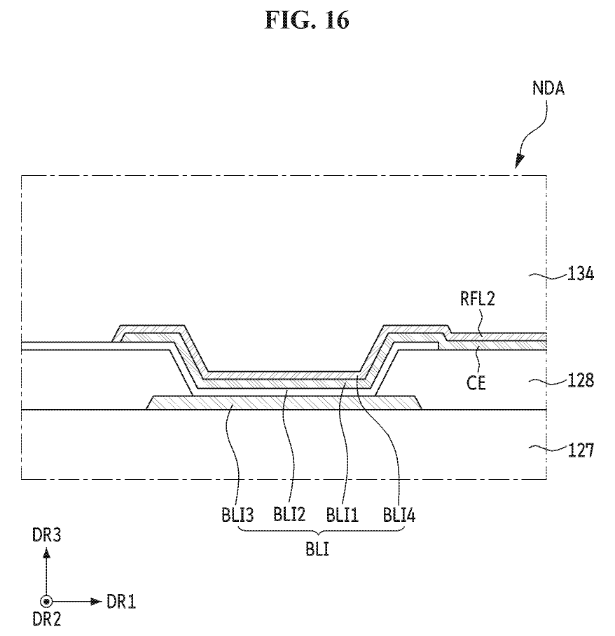

In one or more embodiments, the reflective layer RFL may be located even in the non-display area NDA. For example, the second reflective layer RFL2 may be extended to the non-display area NDA to cover the first wiring layer BLI1 of the power bus line BLI. Accordingly, the power bus line BLI may be appropriately protected in the process of forming the reflective layer RFL and raise the reliability of the display device 1. In one or more embodiments, one portion of the second reflective layer RFL2 covering the first wiring layer BLI1 may form one wiring layer (e.g., fourth wiring layer BLI4 of FIG. 16) among the wiring layers included in the power bus line BLI.

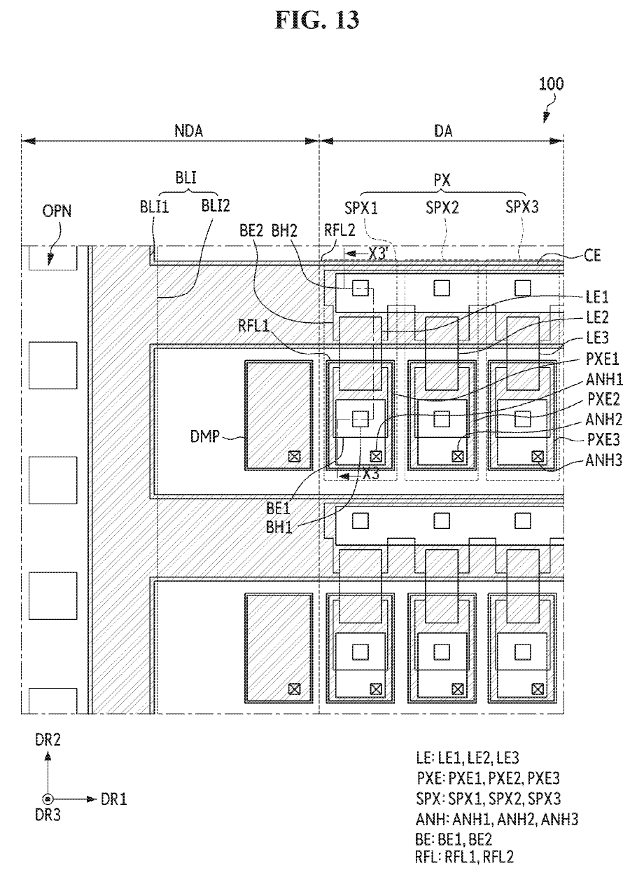

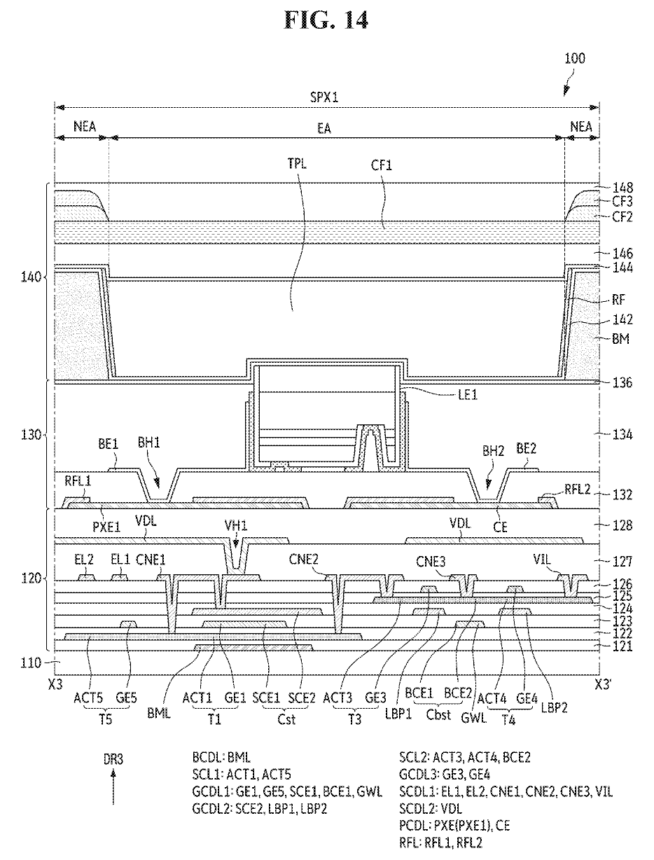

FIG. 13 is a plan view illustrating a display panel according to one or more embodiments. FIG. 14 is a cross-sectional view illustrating a display panel according to one or more embodiments. For example, FIG. 14 shows one or more embodiments of a cross-section of one portion of the display panel 100 taken along the line X3-X3’ of FIG. 13. In comparison with FIGS. 11 and 12, FIGS. 13 and 14 show one or more other embodiments of the reflective layer RFL.

Referring to FIGS. 13 and 14, the reflective layer RFL may cover the end portion of the pixel electrode PXE and the common electrode CE of each of the sub-pixels SPX, while not covering a portion of the top surface of the pixel electrode PXE and the common electrode CE. For example, the first reflective layer RFL1 and the second reflective layer RFL2 may be opened at a portion not overlapping the light-emitting element LE, and may respectively expose a portion of the top surface of the pixel electrodes PXE and a portion of the top surface of the common electrode CE. For example, the first reflective layer RFL1 may be opened at an area where the first connection hole BH1 is located and the periphery thereof, and the second reflective layer RFL2 may be opened at an area where the second connection hole BH2 is located and the periphery thereof.

The first connection electrode BE1 may be in contact with the pixel electrode PXE at the opened portion of the first reflective layer RFL1, and the second connection electrode BE2 may be in contact with the common electrode CE at the opened portion of the second reflective layer RFL2. For example, the first connection electrode BE1 may directly contact and/or may be connected to the pixel electrode PXE in an area corresponding to the first connection hole BH1 (e.g., inside of the first connection hole BH1), and the second connection electrode BE2 may directly contact and/or may be connected to the common electrode CE in an area corresponding to the second connection hole BH2 (e.g., inside of the second connection hole BH2). As the first connection electrode BE1 and the second connection electrode BE2 are in direct connection with the pixel electrode PXE and the common electrode CE, respectively, a contact resistance between the first connection electrode BE1 and the pixel electrode PXE and a contact resistance between the second connection electrode BE2 and the common electrode CE may reduce. Accordingly, a contact quality between the first connection electrode BE1 and the pixel electrode PXE and a contact quality between the second connection electrode BE2 and the common electrode CE may be improved.

In addition, according to the aforementioned embodiments, the first reflective layer RFL1 and the second reflective layer RFL2 may appropriately cover the end portions including the side surfaces of the pixel electrode PXE and the common electrode CE. Accordingly, in the etching process for forming the first reflective layer RFL1 and the second reflective layer RFL2, the end portions of the pixel electrode PXE and the common electrode CE may be covered and protected by a conductive film for forming the first reflective layer RFL1 and the second reflective layer RFL2, or the first reflective layer RFL1 and the second reflective layer RFL2 formed from the conductive film, and thus, may not be exposed to the etchant. Accordingly, in the process of forming the reflective layer RFL or the subsequent process thereafter, damage to the pixel electrodes PXE and the common electrode CE may be reduced or prevented, and the reliability of the sub-pixels SPX and the display device 1 including the sub-pixels SPX may be improved.

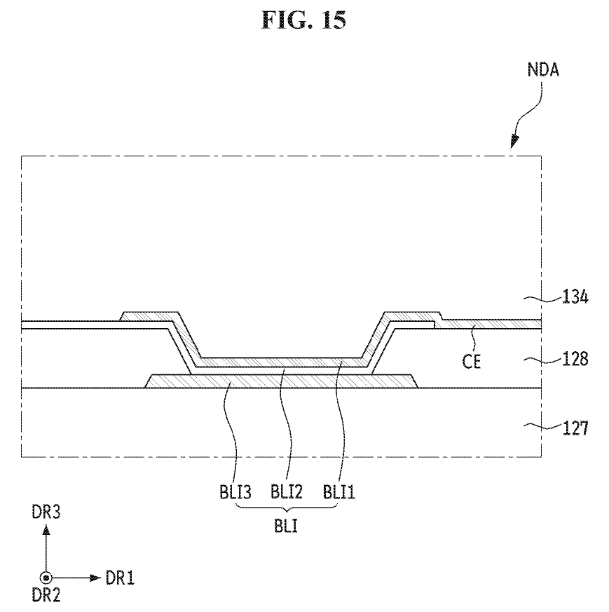

FIG. 15 is a cross-sectional view illustrating a power bus line according to one or more embodiments. For example, FIG. 15 shows a cross-section of one portion of the power bus line BLI illustrated in FIGS. 6 to 8.

Referring to FIG. 15 in addition to FIGS. 6 to 8, the power bus line BLI may include a first wiring layer BLI1 and a second wiring layer BLI2. In one or more embodiments, the power bus line BLI may further include a third wiring layer BLI3.

The first wiring layer BLI1 may be extended from the common electrode CE. For example, the first wiring layer BLI1 may be formed in a three-layer structure (Ti/Al/Ti) of titanium (Ti), aluminum (Al), and titanium (Ti), and the first wiring layer BLI1 and the common electrode CE may be integrally formed.

The second wiring layer BLI2 may be located between the first wiring layer BLI1 and the third wiring layer BLI3. For example, the second wiring layer BLI2 may be located on the seventh insulating layer 128 in the non-display area NDA, and may be in contact with/or connected to the first wiring layer BLI1 directly under the first wiring layer BLI1.

The seventh insulating layer 128 may be opened to expose a portion of the third wiring layer BLI3. For example, the seventh insulating layer 128 may cover the end portion of the third wiring layer BLI3, and may expose the other portion of the third wiring layer BLI3. The second wiring layer BLI2 and the third wiring layer BLIb may be in contact with and/or connected to each other at the opened portion of the seventh insulating layer 128.

In one or more embodiments, the second wiring layer BLI2 may include a material appropriate for protecting the third wiring layer BLI3 in the process of forming the first wiring layer BLI1. For example, each of the first wiring layer BLI1 and the third wiring layer BLI3 may be formed in a three-layer structure (Ti/Al/Ti) of titanium (Ti), aluminum (Al), and titanium (Ti), and the second wiring layer BLI2 may include a transparent conductive oxide, such as indium tin oxide (ITO).

The third wiring layer BLI3 may be formed in a pattern of at least one conductive layer included in the backplane layer 120. For example, the third wiring layer BLI3 may be formed in a pattern of the second source-drain conductive layer SCDL2 located on the sixth insulating layer 127, and may include low-resistance material.

By forming the power bus line BLI in multiple layers as in the above-described embodiments, the resistance of the power bus line BLI may be reduced. Accordingly, the second driving voltage VSS may be stably transmitted to the sub-pixels SPX of the display area DA.

FIG. 16 is a cross-sectional view illustrating a power bus line according to one or more embodiments. For example, FIG. 16 shows one or more embodiments of a cross-section of one portion of the power bus line BLI illustrated in FIGS. 11 to 13.

Referring to FIG. 16 in addition to FIGS. 11 to 15, the power bus line BL may further include a fourth wiring layer BLI4 extended from the second reflective layer RFL2. For example, the fourth wiring layer BLI4 may be formed in a three-layer structure (ITO/Ag/ITO) of indium tin oxide (ITO), silver (Ag), and indium tin oxide (ITO), and the fourth wiring layer BLI4 and the second reflective layer RFL2 may be integrally formed.

The fourth wiring layer BLI4 may be formed on the first wiring layer BLI1. For example, the fourth wiring layer BLI4 may be located directly on the first wiring layer BLI1 in the non-display area NDA, and the first wiring layer BLI1 may be in contact with and/or connected to the first wiring layer BLI1. The fourth wiring layer BLI1 may cover the end portion of the first wiring layer BLI1 to protect the first wiring layer BLI1. For example, the fourth wiring layer BLI4 may completely cover the first wiring layer BLI1.

As described above, the sub-pixel SPX of the display device 1 according to the embodiments may include the reflective layer RFL located under the light-emitting element LE. For example, the sub-pixel SPX may include the pixel electrode PXE and the common electrode CE formed as patterns of the pixel electrode layer PCDL, and may spaced apart from each other, the first reflective layer RFL1 and the second reflective layer RFL2 formed as patterns of the reflective layer RFL and respectively located on the pixel electrode PXE and the common electrode CE, and the light-emitting element LE located on the first reflective layer RFL1 and the second reflective layer RFL2. Accordingly, the light efficiency of the sub-pixel SPX and the display device 1 (or the electronic device) including the sub-pixel SPX may be improved.

In one or more other embodiments, in a case where the light-emitting element LE is a light-emitting element of a vertical type (e.g., a micro LED of a vertical type), the patterns of the pixel electrode layer PCDL may include pixel electrodes PXE, and the common electrode CE may be located (for example, located as a common layer on the entire surface) on the light-emitting elements LE located on the pixel electrodes PXE. In this case, as the reflective layer RFL (e.g., first reflective layer RFL1), the light-emitting element LE, and the common electrode CE are sequentially located on top of each of the pixel electrodes PXE, the light efficiency of the sub-pixel SPX and the display device 1 including the sub-pixel SPX may be improved.

In some embodiments, the reflective layer RFL may cover the end portion of the pixel electrode layer PCDL and protect the pixel electrode layer PCDL. For example, the first reflective layer RFL1 may cover the end portion of the pixel electrode PXE, and the second reflective layer RFL2 may cover the end portion of the common electrode CE. Accordingly, the damage of the pixel electrode PXE and the common electrode CE may be reduced or prevented, and the reliability of the display device 1 may be secured and improved.

The display device 1 according to at least one of the above-described embodiments may be applied to various electronic devices. The electronic device according to one or more embodiments may include the above-described display device 1 (or a display module including the display panel 100 according to at least one or more embodiments), and may further include modules or devices having other additional functions in addition to the display device 1.

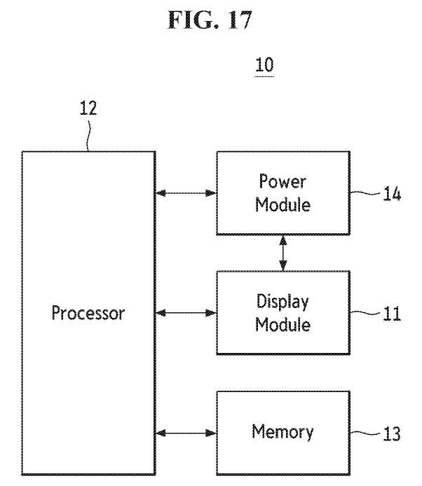

FIG. 17 is a block diagram of an electronic device according to one or more embodiments. Referring to FIG. 17, an electronic device 10 according to one or more embodiments may include a display module 11, a processor 12, a memory 13, and a power module 14.

The electronic device 10 may output various information in the form of images through the display module 11. For example, when the processor 12 executes an application stored in the memory 13, image information provided by the application may be provided to a user through the display module 11.

The display module 11 may include the display panel 100 for displaying an image. For example, the display module 11 may include the display panel 100 according to at least one of the aforementioned embodiments.

The processor 12 may include at least one of a central processing unit (CPU), an application processor (AP), a graphic processing unit (GPU), a communication processor (CP), an image signal processor (ISP), or a controller.

The memory 15 may store data information required for the operation of the processor 12 or the display module 11. For example, the memory 15 may store an image data signal and/or an input control signal.

The processor 12 may control the display module 11 using information stored in the memory 15. The processor 12 may transmit the image data signal and/or the input control signal stored in the memory 15 to the display module 11. For example, when the processor 12 executes an application stored in the memory 15, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power required for the operation of the electronic device 10.

At least one of the components of the electronic device 10 described above may be included in the display device 1 according to the embodiments described above. Further, some of individual modules functionally included in one module may be included in the display device 1 and some others may be provided separately from the display device 1. For example, the display device 1 may include the display module 11, and the processor 12, the memory 13, and the power module 14 may be provided in the form of other devices in the electronic device 10 other than the display device 1.

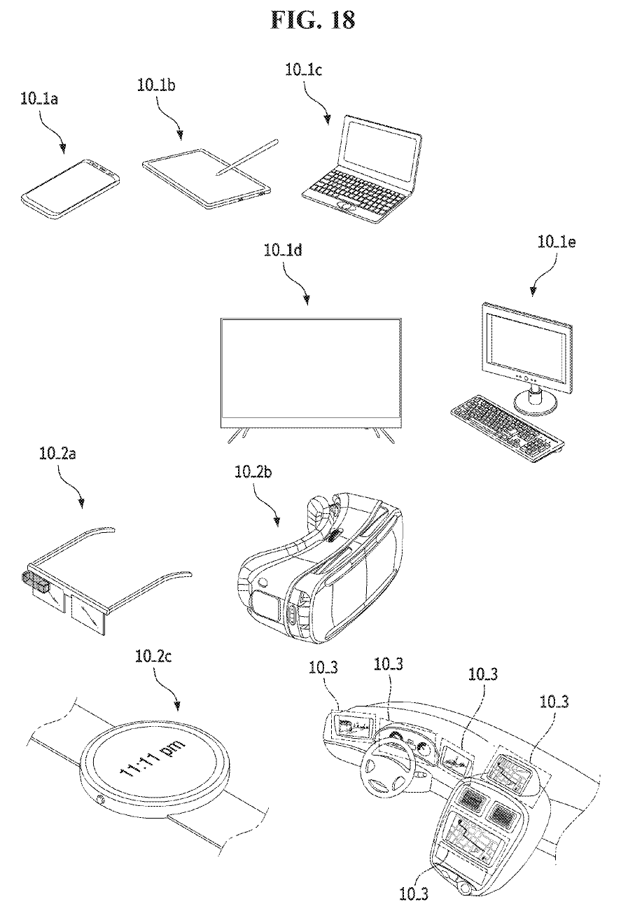

FIG. 18 is schematic views of electronic devices according to various embodiments.

Referring to FIG. 18, various electronic devices to which the display device 1 according to embodiments is applied may include not only an image display electronic device, such as a smartphone 10_1a, a tablet PC 10_1b, a laptop 10_1c, a TV 10_1d, and a desk monitor 10_1e, but also a wearable electronic device including a display module, such as smart glasses 10_2a, a head mounted display 10_2b, or a smart watch 10_2c, a vehicle electronic device 10_3 including a display module, such as a center fascia, and a dashboard of an automobile, a center information display (CID) placed on the dashboard, a room mirror display, and the like.

In concluding the detailed description, those skilled in the art will appreciate that many variations and modifications can be made to the embodiments without substantially departing from the aspects of the present disclosure. Therefore, the disclosed embodiments are used in a generic and descriptive sense only and not for purposes of limitation.

What is claimed is:

1. A display device comprising:
a pixel electrode and a common electrode spaced apart above a substrate;
a first reflective layer and a second reflective layer separated from each other and respectively above the pixel electrode and the common electrode; and
a light-emitting element above the first reflective layer and the second reflective layer and electrically connected between the pixel electrode and the common electrode.

2. The display device of claim 1, wherein the first reflective layer is above an end portion of the pixel electrode overlapping the light-emitting element, and exposes another portion of the pixel electrode.

3. The display device of claim 2, wherein the second reflective layer is above an end portion of the common electrode overlapping the light-emitting element and adjacent to the pixel electrode, and exposes another portion of the common electrode.

4. The display device of claim 3, wherein the first reflective layer covers a side surface of the end portion of the pixel electrode, and
wherein the second reflective layer covers a side surface of the end portion of the common electrode.

5. The display device of claim 2, wherein the first reflective layer has a length that is less than a length of the pixel electrode in an extension direction of the pixel electrode, has a width that is greater than a width of the pixel electrode in a second direction crossing the extension direction, covers the end portion of the pixel electrode, and exposes another end portion of the pixel electrode.

6. The display device of claim 5, wherein the first reflective layer and the second reflective layer are symmetrical with respect to the light-emitting element.

7. The display device of claim 1, wherein the first reflective layer covers a side surface of an end portion of the pixel electrode, and
wherein the second reflective layer covers a side surface of an end portion of the common electrode.

8. The display device of claim 7, wherein the first reflective layer entirely covers the pixel electrode, and
wherein the second reflective layer entirely covers the common electrode.

9. The display device of claim 7, wherein the first reflective layer exposes a portion of a top surface of the pixel electrode not overlapping the light-emitting element, and
wherein the second reflective layer exposes a portion of a top surface of the common electrode not overlapping the light-emitting element.

10. The display device of claim 1, further comprising:
an adhesive layer covering a portion of the first reflective layer and a portion of the second reflective layer below and overlapping the light-emitting element;
a first connection electrode above the adhesive layer and connecting the pixel electrode or the first reflective layer and the light-emitting element; and
a second connection electrode above the adhesive layer and connecting the common electrode or the second reflective layer and the light-emitting element.

11. The display device of claim 10, wherein the first connection electrode contacts the light-emitting element above the portion of the first reflective layer, and contacts the first reflective layer above another portion of the first reflective layer, and
wherein the second connection electrode contacts the light-emitting element above the portion of the second reflective layer, and contacts the second reflective layer above another portion of the second reflective layer.

12. The display device of claim 10, wherein the first reflective layer and the second reflective layer respectively expose a top surface of the pixel electrode contacting the first connection electrode, and a top surface of the common electrode contacting the second connection electrode.

13. The display device of claim 10, wherein the light-emitting element comprises:
a semiconductor stack above the adhesive layer;
a first contact electrode on at least one side surface of the semiconductor stack and contacting the first connection electrode above the first reflective layer; and
a second contact electrode on at least one side surface of the semiconductor stack and contacting the second connection electrode above the second reflective layer.

14. The display device of claim 1, further comprising a power bus line electrically connected to the common electrode and comprising a wiring layer extended from the common electrode.

15. The display device of claim 14, wherein the second reflective layer extends to and covers the wiring layer.

16. An electronic device comprising:
a display module comprising a display panel;
a memory for storing an image data signal or an input control signal; and
a processor for transmitting the image data signal or the input control signal to the display module,
wherein the display panel comprises:
a pixel electrode and a common electrode spaced apart from each other above a substrate;
a first reflective layer and a second reflective layer separated from each other and respectively above the pixel electrode and the common electrode; and
a light-emitting element above the first reflective layer and the second reflective layer and electrically connected between the pixel electrode and the common electrode.

17. The electronic device of claim 16, wherein the first reflective layer is above an end portion of the pixel electrode overlapping the light-emitting element, and exposes another portion of the pixel electrode, and
wherein the second reflective layer is above an end portion of the common electrode overlapping the light-emitting element and adjacent to the pixel electrode, and exposes another portion of the common electrode.

18. The electronic device of claim 16, wherein the first reflective layer covers a side surface of an end portion of the pixel electrode, and
wherein the second reflective layer covers a side surface of an end portion of the common electrode.

19. The electronic device of claim 18, wherein the first reflective layer entirely covers the pixel electrode, and
wherein the second reflective layer entirely covers the common electrode.

20. The electronic device of claim 18, wherein the first reflective layer exposes a portion of a top surface of the pixel electrode not overlapping the light-emitting element, and
wherein the second reflective layer exposes a portion of a top surface of the common electrode not overlapping the light-emitting element.
